(19) United States
(12) Patent Application Publication
(10) Pub. No.: US 2025/0104760 A1
(43) Pub. Date: Mar. 27, 2025

(54) STACKED MEMROY LAYERS WITH GLOBAL BIT LINE OR GLOBAL WORD LINE

(71) Applicant: Intel Corporation, Santa Clara, CA (US)

(72) Inventors: Abhishek A. Sharma, Portland, OR (US); Sagar Suthram, Portland, OR (US); Wilfred Gomes, Portland, OR (US); Anand S. Murthy, Portland, OR (US); Tahir Ghani, Portland, OR (US); Pushkar Sharad Ranade, San Jose, CA (US)

(73) Assignee: Intel Corporation, Santa Clara, CA (US)

(21) Appl. No.: 18/471,382

(22) Filed: Sep. 21, 2023

(51) Int. Cl. G11C 11/4091; G11C 11/408; G11C 11/4094

(52) U.S. Cl. CPC G11C 11/4091; G11C 11/4085; G11C 11/4094

(57) ABSTRACT

An IC device may include memory layers over a logic layer. A memory layer includes memory arrays, each of which includes memory cells arranged in rows and columns. A row of memory cells may be associated with a word line. A column of memory cells may be associated with a bit line. Bit lines of different memory arrays may be coupled using one or more vias or source/drain electrodes of transistors in the memory arrays. Alternatively, word lines of different memory arrays may be coupled using one or more vias or gate electrodes of transistors in the memory arrays. The logic layer has a logic circuit that can control data read operations and data write operations of the memory layers. The logic layer may include a power interconnect, which facilitates power delivery to the memory layers, and a signal interconnect, which facilitates signal transmission within the memory device.

### BACKGROUND

Integrated circuit (IC) devices with memory circuitry are important to the performance of modern system-on-a-chip (SoC) technology. IC fabrication usually includes two stages. The first stage is referred to as the front end of line (FEOL). The second stage is referred to as the back end of line (BEOL). In the FEOL, individual semiconductor devices components (e.g., transistor, capacitors, resistors, etc.) can be patterned on a wafer. In the BEOL, metal layers, vias, and insulating layers can be formed to get the individual components interconnected. The BEOL usually starts with forming the first metal layer on the wafer. The first metal layer is often called M0. More metal layers can be formed on top of M0, and these metal layers are often called M1, M2, and so on.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 illustrates an IC device including a stack of memory devices with global bit lines, according to some embodiments of the disclosure.

FIG. 2 illustrates an IC device including a stack of memory devices with global word lines, according to some embodiments of the disclosure.

FIG. 3 illustrates an IC device including a logic die with a power interconnect and a signal interconnect for power and signal delivery and memory dies over the logic die, according to some embodiments of the disclosure.

FIG. 4 illustrates an IC device with transistors having global gate electrodes, according to some embodiments of the disclosure.

FIG. 5 illustrates an IC device with transistors having global source or drain electrodes, according to some embodiments of the disclosure.

FIG. 6A illustrates semiconductor regions of a transistor in a memory die, according to some embodiments of the disclosure.

FIG. 6B illustrates semiconductor regions of a transistor in a logic die, according to some embodiments of the disclosure.

FIG. 7 illustrates an IC device including memory wafers over a logic wafer, according to some embodiments of the disclosure.

FIG. 8 illustrates an IC device with global lines, according to some embodiments of the present disclosure.

FIG. 9A is an electric circuit diagram of an example memory cell, according to some embodiments of the present disclosure.

FIG. 9B provides a top-down plan view of one example implementation of the memory cell, according to some embodiments of the present disclosure.

FIG. 10 is an IC device with memory layers sharing word line drivers in a complementary metal-oxide-semiconductor (CMOS) layer, according to some embodiments of the disclosure.

FIG. 11 illustrates an IC device with memory layers sharing sense amplifiers in a CMOS layer, according to some embodiments of the disclosure.

FIG. 12 illustrates an IC device with memory layers sharing word line drivers and sense amplifiers in a CMOS layer, according to some embodiments of the present disclosure.

FIGS. 13A and 13B are top views of a wafer and dies that can facilitate stacked memory layers with one or more global bit lines or one or more global word lines, according to some embodiments of the disclosure.

FIG. 14 is a side, cross-sectional view of an example IC package that may include stacked memory layers with one or more global bit lines or one or more global word lines, according to some embodiments of the disclosure.

FIG. 15 is a cross-sectional side view of an IC device assembly that may include components having stacked memory layers with one or more global bit lines or one or more global word lines, according to some embodiments of the disclosure.

FIG. 16 is a block diagram of an example computing device that may include one or more components with stacked memory layers with one or more global bit lines or one or more global word lines, according to some embodiments of the disclosure.

### DETAILED DESCRIPTION

The systems, methods, and devices of this disclosure each have several innovative aspects, no single one of which is solely responsible for all the desirable attributes disclosed herein. Details of one or more implementations of the subject matter described in this specification are set forth in the description below and the accompanying drawings.

Embodiments of the present disclosure are applicable to different types of memory devices. Some embodiments of the present disclosure may refer to static random-access memory (SRAM). Other embodiments of the present disclosure may refer to dynamic random-access memory (DRAM). However, embodiments of the present disclosure may be equally applicable to memory cells implemented other technologies. Thus, in general, memory cells/arrays described herein may be implemented as standalone SRAM devices, DRAM devices, or any other volatile or nonvolatile memory cells/arrays.

A memory cell is a fundamental building block of computer memory devices used to store and retrieve data. It is a small unit of storage that can hold a single bit of information, which can be either a 0 or a 1. Memory cells are organized in a grid-like structure to form memory arrays. A SRAM cell may include a plurality of transistors for storing a bit value or a memory state (e.g., logic “1” or “0”) of the memory cell and one or more access transistors for controlling access to the memory cell (e.g., access to write data to the cell or access to read data from the cell). SRAM is used in many different computer products and further improvements are always desirable. A memory array also includes word lines and bit lines coupled to memory cells. A word line can be used to control the access to a specific row of memory cells in the memory array. When the word line is activated, it enables the data stored in the selected row to be read or modified. A bit line can couple the memory cells in the memory array to the memory control circuitry. A bit line can be used for reading and writing data.

Memory arrays can be arranged in memory layers. A memory layer may be a die. Memory layers may be arranged in a stack. Performance of memory devices (e.g., memory bandwidth) is often limited by the number of memory arrays that can be implemented in a memory layer or the number of memory layers that can be stacked in the available memory area. For example, currently available memory devices often require flow control circuits in memory dies. With the presence of the flow control circuits, the space for arranging memory arrays in a memory die is limited. As another example, currently available memory devices require power delivery structures in memory dies. The power delivery structures are usually implemented in BEOL metal layers, which can make the memory die “thicker” so that the number of memory dies that can be arranged in the available memory would be limited.

Embodiments of the present disclosure may improve on at least some of the challenges and issues described above by providing stacked memory layers with one or more global bit lines or one or more global word lines. A global bit line is a bit line in a memory layer that is coupled to one or more bit lines in one or more other memory layers over the memory layer. A global word line is a word line in a memory layer that is coupled to one or more word lines in one or more other memory layers over the memory layer.

In various embodiments of the present disclosure, an IC device may include a stack of memory layers over a logic layer. Each memory layer may be a memory die or memory wafer. The logic layer may be a logic die or logic wafer. An example memory layer includes memory arrays, each of which includes memory cells arranged in rows and columns. A row of memory cells may be associated with a word line. A column of memory cells may be associated with a bit line. Bit lines (or word lines) in different memory layers may be coupled to each other by one or more vias connected to the bit lines (or word lines). Additionally or alternatively, bit lines in different memory layers may be coupled to each other through gate electrodes of transistors in the memory layers. Word lines in different memory layers may be coupled to each other through source electrodes or drain electrodes of transistors in the memory layers.

The logic layer may have one or more logic circuits that can control data read operations and data write operations of the memory layers. The logic layers may include one or more semiconductor structures, which may be or include semiconductor regions of transistors. A semiconductor structure in the logic layer may have a larger dimension than a semiconductor structure in a memory layer. The logic layer may also include a power interconnect, which facilitates power delivery to the memory layers, and a signal interconnect, which facilitates signal transmission within the memory device. Given the presence of global bit lines or global word lines, the logic layer may transmit a global signal to multiple memory layers at a time. Each memory layer may include no peripheral circuit or power delivery components so that the number of memory arrays in the memory layer can be maximized.

It should be noted that, in some settings, the term “nanoribbon” has been used to describe an elongated semiconductor structure that has a substantially rectangular transverse cross section (e.g., a cross section in a plane perpendicular to the longitudinal axis of the structure), while the term “nanowire” has been used to describe a similar structure but with a substantially circular or square transverse cross-sections. In the following, a single term “nanoribbon” is used to describe an elongated semiconductor structure independent of the shape of the transverse cross section. Thus, as used herein, the term “nanoribbon” is used to cover elongated semiconductor structures that have substantially rectangular transverse cross-sections (possibly with rounded corners), elongated semiconductor structures that have substantially square transverse cross-sections (possibly with rounded corners), elongated semiconductor structures that have substantially circular or elliptical/oval transverse cross-sections, as well as elongated semiconductor structures that have any polygonal transverse cross-sections. A longitudinal axis of a structure refers to a line (e.g., an imaginary line) that runs down the center of the structure in a direction perpendicular to a transverse cross section of the structure.

In the following, some descriptions may refer to a particular source or drain (S/D) region or contact being either a source region/contact or a drain region/contact. However, unless specified otherwise, which region/contact of a transistor or diode is considered to be a source region/contact and which region/contact is considered to be a drain region/contact is not important because, as is common in the field of FETs, designations of source and drain are often interchangeable. Therefore, descriptions of some illustrative embodiments of the source and drain regions/contacts provided herein are applicable to embodiments where the designation of source and drain regions/contacts may be reversed.

As used herein, the term “metal layer” may refer to a layer above a substrate that includes electrically conductive interconnect structures for providing electrical connectivity between different IC components. Metal layers described herein may also be referred to as “interconnect layers” to clearly indicate that these layers include electrically conductive interconnect structures which may, but do not have to be, metal.

The systems, methods and devices of this disclosure each have several innovative aspects, no single one of which is solely responsible for all of the desirable attributes disclosed herein. Details of one or more implementations of the subject matter described in this specification are set forth in the description below and the accompanying drawings.

In the following detailed description, various aspects of the illustrative implementations may be described using terms commonly employed by those skilled in the art to convey the substance of their work to others skilled in the art. For example, the term “connected” means a direct electrical or magnetic connection between the things that are connected, without any intermediary devices, while the term “coupled” means either a direct electrical or magnetic connection between the things that are connected, or an indirect connection through one or more passive or active intermediary devices. The term “circuit” means one or more passive and/or active components that are arranged to cooperate with one another to provide a desired function. If used, the terms “oxide,” “carbide,” “nitride,” etc. refer to compounds containing, respectively, oxygen, carbon, nitrogen, etc., the term “high-k dielectric” refers to a material having a higher dielectric constant (k) than silicon oxide, while the term “low-k dielectric” refers to a material having a lower k than silicon oxide.

The terms “substantially,” “close,” “approximately,” “near,” and “about,” generally refer to being within +/−20% of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−5-20% of a target value based on the context of a particular value as described herein or as known in the art.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

For the purposes of the present disclosure, the term “or” refers to an inclusive “or” and not to an exclusive “or.” The phrase “A and/or B” or the phase “A or B” means (A), (B), or (A and B). For the purposes of the present disclosure, the phrase “A, B, and/or C” or the phase “A, B, or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

The description may use the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

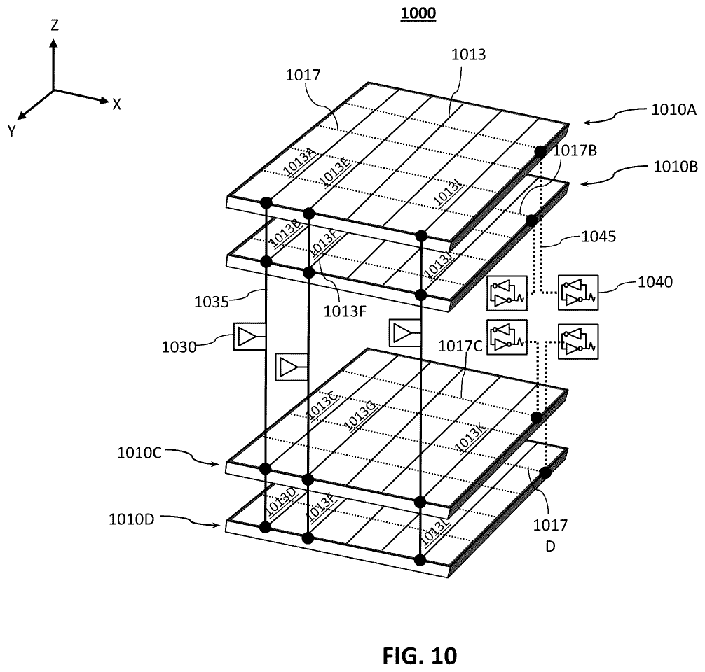

In the following detailed description, reference is made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense. For convenience, if a collection of drawings designated with different letters are present, e.g., FIGS. 10A and 10B, such a collection may be referred to herein without the letters, e.g., as “FIG. 10.”

In the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross section of a device to detect the shape and the location of various device elements described herein using e.g., Physical Failure Analysis (PFA) would allow determination of presence of stacked memory layers with one or more global bit lines or one or more global word lines as described herein.

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

Various stacked memory layers with one or more global bit lines or one or more global word lines as described herein may be implemented in, or associated with, one or more components associated with an IC or/and may be implemented between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

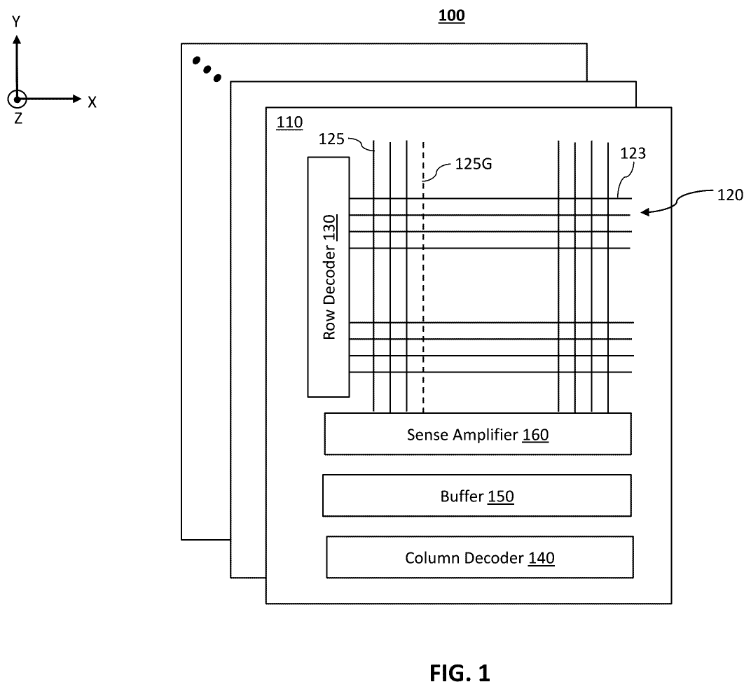

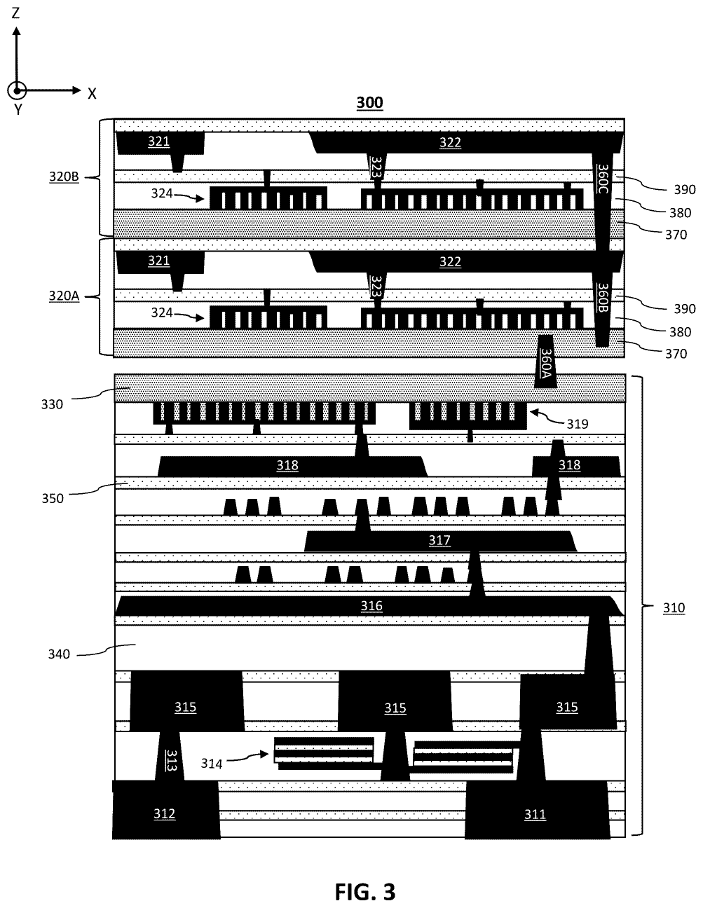

FIG. 1 illustrates an IC device 100 including a stack of memory devices 110 with global bit lines, according to some embodiments of the disclosure. The IC device 100 may also be referred to as an IC assembly. The memory devices 110 are stacked over each other along the Z axis. Different memory devices 110 in the IC device 100 may be in different memory layers, e.g., memory dies or memory wafers. In some embodiments, a memory device 110 may be in a memory die, e.g., the memory die 320A or 320B in FIG. 3. As shown in FIG. 1, each memory device 110 includes a memory array 120, a row decoder 130, a column decoder 140, a buffer 150, and a sense amplifier 160. In other embodiments, a memory device 110 may include fewer, more, or different components. In some embodiments, the row decoder 130, column decoder 140, buffer 150, and sense amplifier 160 in a memory device 110 may be local to the memory array 120 in the same memory device 110, i.e., they are coupled to the memory array 120 in the same memory device 110 but are not coupled to memory arrays in other memory devices 110. In some embodiments, the memory device 110 may be referred to as a memory array, which includes the row decoder 130, column decoder 140, buffer 150, and sense amplifier 160 in addition to the memory cells, word lines 123, and bit lines 125.

The memory array 120 includes word lines 123 (individually referred to as “word line 123”), bit lines 125 (individually referred to as “bit line 125”), and a plurality of memory cells. A memory cell may be coupled to a bit line 125 and a word line 123. In some embodiments, the memory cells in the memory array 120 are arranged in rows and columns. A row of memory cells may be coupled to a word line 123. The word line 123 may be used to access the memory cells in the row. For instance, when the word line 123 is activated, the row of memory cells may be selected and accessed for data read operations or data write operations. The word lines 123 may also be referred to as row select lines. A column of memory cells may be connected to a bit line 125. The bit line 125 may be used to access the memory cells in the column. For instance, when the bit line 125 is activated, the column of memory cells may be selected and accessed for data read operations or data write operations. In some embodiments, each column of memory cells is connected to two bit lines 125: a first bit line 125 and a second bit line 125 that is the inverse of the first bit line 125. A bit of data may be stored in a column of memory cells.

The bit lines 125 includes a global bit line 125G. The global bit line 125G is coupled to one or more other global bit lines 125G in one or more other memory devices 110. In an example, these global bit lines may be coupled to each other by one or more vias. The coupled global bit lines may be at the same or similar voltages during operations of corresponding memory devices 110. A via may have an end connected to the global bit line 125G and another end connected to a global bit line in another memory device 110. The via may have a longitudinal axis along the Z axis. In some embodiments, a via may be a TSV. Multiple vias coupling global bit lines may constitute a zigzag pattern in some embodiments.

Signals or power may be propagated from the global bit line 125G to the one or more other global bit lines coupled to the global bit line 125G. Additionally or alternatively, signals or power may be propagated from another global bit line to the global bit line 125G. With these global bit lines, the columns of memory cells associated with the global bit lines may be accessed at the same time or with the same control signal(s). Even though FIG. 1 shows a single global bit line 125G in one memory device 110, a memory device 110 in the IC device 100 may include multiple one global bit lines. Also, one or more memory devices 110 in the IC device 100 may include zero global bit line.

In some embodiments, a memory cell may include one or more transistors, e.g., one or more access transistors. A transistor in a memory cell may receive power from a logic layer, such as a logic die or a logic wafer. For instance, an electrode over the source or drain region of the transistor may be coupled to a power via, and the power via may be coupled to a power interconnect in the logic die. Additionally or alternatively, the transistor may receive a signal from the logic layer. For instance, a gate electrode in the transistor may be coupled to a signal via, and the signal via may be coupled to a signal interconnect in the logic die. For the purpose of simplicity and illustration, the memory cells are not shown in FIG. 1.

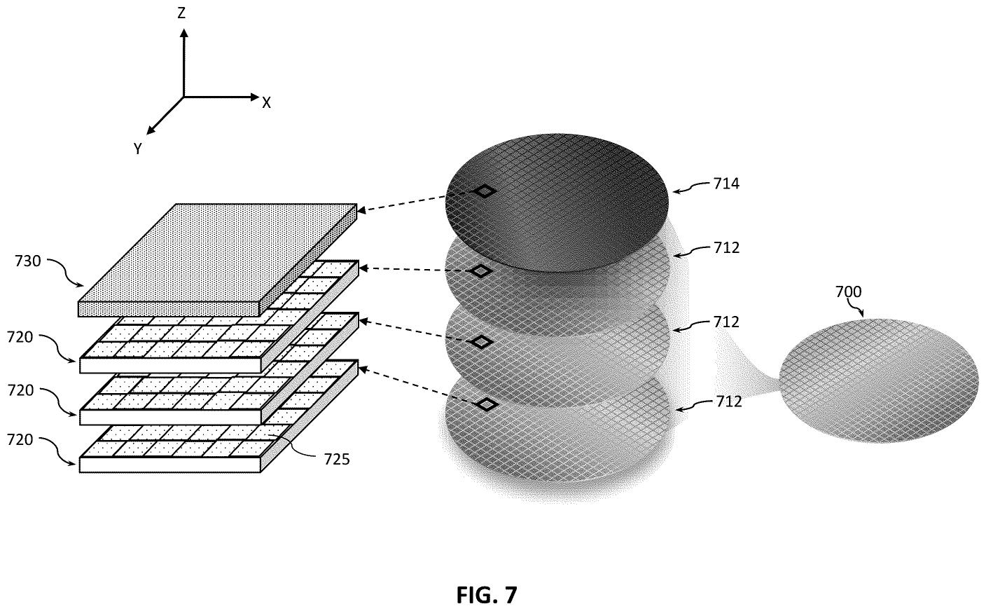

The row decoder 130 selects which rows of memory cells to be accessed based on memory addresses received from a logic circuit, such as a circuit in a logic die (e.g., the logic die 310 in FIG. 3, the logic die 730 in FIG. 7, etc.). In some embodiments, the row decoder 130 may receive an input signal with information indicating a memory address. The row decoder 130 may decode the memory address and select the row(s) corresponding to the memory address. The row decoder 130 may further activate the row(s), e.g., by selecting and enabling the word line 123 of each selected row. After a row is selected and activated, the logic circuit can perform read or write operations on the memory cells in the row. In some embodiments, the row decoder 130 may further include a row driver for each word line 123 to drive a signal down the word line 123. The row decoder 130 may include a digital circuit that can be used to decode memory addresses, select rows of memory cells, or activate word lines 123. The digital circuit may include one or more logic gates. In some embodiments, the row decoder 130 may include one or more inverters to drive the word line 123.

The column decoder 140 selects which column(s) of memory cells to be accessed based on memory addresses received from a logic circuit, such as a circuit in a logic die (e.g., the logic die 310 in FIG. 3, the logic die 730 in FIG. 7, etc.). The column decoder 140 may decode a column address and activate the corresponding column of memory cells. The column decoder 140 may include a digital circuit that can take the column address as input and generate one or more control signals that activate the corresponding column of memory cells. The digital circuit may include a combination of logic gates, such as AND gates and inverters, to decode the address and generate the necessary control signals. The number of inputs and outputs of the column decoder 140 may depend on the size of the memory array 120. For example, in a memory system with 8 columns, the memory column decoder would have 3 address inputs (since 2\hat{ }3=8) and 8 output signals, each corresponding to a specific column. When a particular column address is provided, the column decoder 140 may activate the corresponding output signal, enabling the memory cells in that column for read or write operations. The row decoder 130 and column decoder 140 can facilitate efficient and accurate access to specific rows of memory cells within the memory array 120 and can support retrieval and storage of data in computer systems.

The buffer 150 temporarily stores data, such as signals received by or generated by the memory device 110. In some embodiments, the buffer 150 may facilitate transmission of signals between the memory device 110 and another memory device 110 or between the memory device 110 and a control circuit. The control circuit may be a logic circuit in a logic die (such as a circuit in a logic die (e.g., the logic die 310 in FIG. 3, the logic die 730 in FIG. 7, etc.)). The buffer 150 can speed up signal transmission in embodiments where there is a relatively large distance (e.g., 1 micron or greater) between the memory device 110 and the other memory device 110 or between the memory device 110 and the control circuit.

In some embodiments, signals may pass through the buffer 150 before they arrive at the memory array 120. For example, a read request may be sent from a logic circuit, arrive at the memory device 110, then pass through the buffer 150 to the sense amplifier 160, the column decoder 140, the row decoder 130, the memory array 120, or some combination thereof. The read data may travel back from the memory array 120 to the logic circuit through the buffer 150. In an embodiment, the read request may be stored in the buffer temporarily before the read request is transmitted to the sense amplifier 160, the column decoder 140, the row decoder 130, or the memory array 120. Similarly, the read data may be stored in the buffer temporarily before the read data is transmitted to the control circuit.

The sense amplifier 160 may amplify and restore weak signals, e.g., to a more robust and usable level. In some embodiments, for reading data from the memory array 120, the sense amplifier 160 may detect and amplify the small voltage difference between the stored data states, typically representing binary values of 0 and 1. By amplifying this voltage difference, the sense amplifier 160 can enable accurate and reliable data retrieval. In some embodiments (e.g., embodiments having high speed data transmission), the sense amplifier 160 may amplify weak signals to avoid signal degradation and noise during signal propagation so that the signals can be more immune to noise, which can enable more accurate data recovery. The sense amplifier 160 may be a latch-based sense amplifier, differential sense amplifier, dynamic sense amplifier, or other types of sense amplifiers.

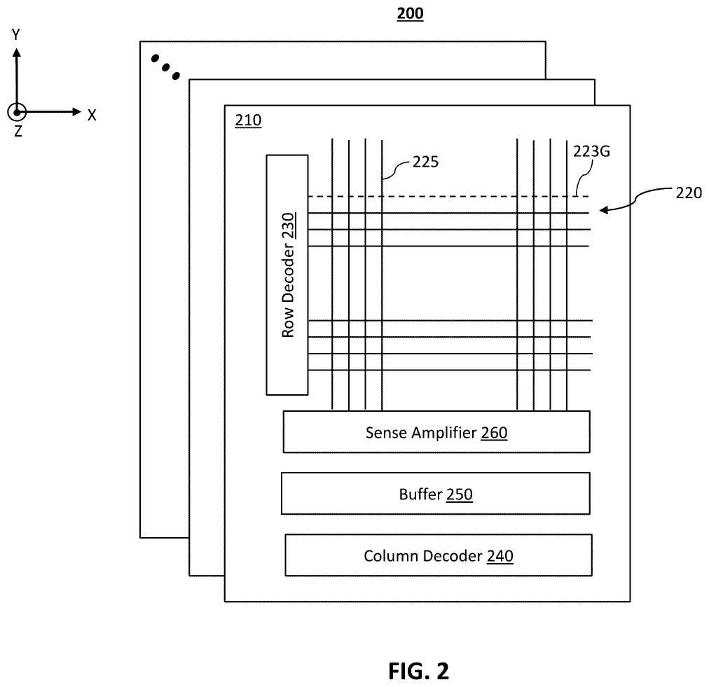

FIG. 2 illustrates IC device 200 including a stack of memory devices 210 with global word lines, according to some embodiments of the disclosure. The IC device 200 may also be referred to as an IC assembly. The memory devices 210 are stacked over each other along the Z axis. Different memory devices 210 in the IC device 200 may be in different memory layers, e.g., memory dies or memory wafers. In some embodiments, a memory device 210 may be in a memory die, e.g., the memory die 320A or 320B in FIG. 3. As shown in FIG. 2, each memory device 210 includes a memory array 220, a row decoder 230, a column decoder 240, a buffer 250, and a sense amplifier 260. In other embodiments, a memory device 210 may include fewer, more, or different components. In some embodiments, the row decoder 230, column decoder 240, buffer 250, and sense amplifier 260 in a memory device 210 may be local to the memory array 220 in the same memory device 210, i.e., they are coupled to the memory array 220 in the same memory device 210 but are not coupled to memory arrays in other memory devices 210. In some embodiments, the memory device 210 may be referred to as a memory array, which includes the row decoder 230, column decoder 240, buffer 250, and sense amplifier 260 in addition to the memory cells, word lines 223, and bit lines 225.

The memory array 220 includes word lines 223 (individually referred to as “word line 223”), bit lines 225 (individually referred to as “bit line 225”), and a plurality of memory cells. A memory cell may be coupled to a bit line 225 and a word line 223. In some embodiments, the memory cells in the memory array 220 are arranged in rows and columns. A row of memory cells may be coupled to a word line 223. The word line 223 may be used to access the memory cells in the row. For instance, when the word line 223 is activated, the row of memory cells may be selected and accessed for data read operations or data write operations. The word lines 223 may also be referred to as row select lines. A column of memory cells may be connected to a bit line 225. The bit line 225 may be used to access the memory cells in the column. For instance, when the bit line 225 is activated, the column of memory cells may be selected and accessed for data read operations or data write operations. In some embodiments, each column of memory cells is connected to two bit lines 225: a first bit line 225 and a second bit line 225 that is the inverse of the first bit line 225. A bit of data may be stored in a column of memory cells.

The word lines 223 includes a global word line 223G. The global word line 223G is coupled to one or more other global word lines 223G in one or more other memory devices 210. In an example, these global bit lines may be coupled to each other by one or more vias. The coupled global bit lines may be at the same or similar voltages during operations of corresponding memory devices 210. A via may have an end connected to the global word line 223G and another end connected to a global bit line in another memory device 210. The via may have a longitudinal axis along the Z axis. In some embodiments, a via may be a TSV. Multiple vias coupling global bit lines may constitute a zigzag pattern in some embodiments.

Signals or power may be propagated from the global word line 223G to the one or more other global bit lines coupled to the global word line 223G. Additionally or alternatively, signals or power may be propagated from another global bit line to the global word line 223G. With these global bit lines, the rows of memory cells corresponding to the global word lines may be accessed at the same time or with the same control signal(s). Even though FIG. 2 shows a single global word line 223G in one memory device 210, a memory device 210 in the IC device 200 may include multiple one global bit lines. Also, one or more memory devices 210 in the IC device 200 may include zero global bit line.

In some embodiments, a memory cell may include one or more transistors. A transistor in a memory cell may receive power from a logic layer, such as a logic die or logic wafer. For instance, an electrode over the source or drain region of the transistor may be coupled to a power via and the power via may be coupled to a power interconnect in the logic die. Additionally or alternatively, the transistor may receive a signal from the logic layer. For instance, a gate electrode in the transistor may be coupled to a signal via, and the signal via may be coupled to a signal interconnect in the logic die. For the purpose of simplicity and illustration, the memory cells are not shown in FIG. 2.

The row decoder 230 selects which rows of memory cells to be accessed based on memory addresses received from a logic circuit, such as a circuit in a logic die (e.g., the logic die 310 in FIG. 3, the logic die 730 in FIG. 7, etc.). In some embodiments, the row decoder 230 may receive an input signal with information indicating a memory address. The row decoder 230 may decode the memory address and select the row(s) corresponding to the memory address. The row decoder 230 may further activates the row(s), e.g., by selecting and enabling the word line 223 of each selected row. After a row is selected and activated, the logic circuit can perform read or write operations on the memory cells in the row. In some embodiments, the row decoder 230 may further include a row driver for each word line 223 to drive a signal down the word line 223. The row decoder 230 may include a digital circuit that can be used to decode memory addresses, select rows of memory cells, or activate word lines 223. The digital circuit may include one or more logic gates. In some embodiments, the row decoder 230 may include one or more inverters to drive the word line 223.

The column decoder 240 selects which column(s) of memory cells to be accessed based on memory addresses received from a logic circuit, such as a circuit in a logic die (e.g., the logic die 310 in FIG. 3, the logic die 730 in FIG. 7, etc.). The column decoder 240 may decode a column address and activate the corresponding column of memory cells. The column decoder 240 may include a digital circuit that can take the column address as input and generate one or more control signals that activate the corresponding column of memory cells. The digital circuit may include a combination of logic gates, such as AND gates and inverters, to decode the address and generate the necessary control signals. The number of inputs and outputs of the column decoder 240 may depend on the size of the memory array 220. For example, in a memory system with 8 columns, the memory column decoder would have 3 address inputs (since 2\hat{ }3=8) and 8 output signals, each corresponding to a specific column. When a particular column address is provided, the column decoder 240 may activate the corresponding output signal, enabling the memory cells in that column for read or write operations. The row decoder 230 and column decoder 240 can facilitate efficient and accurate access to specific rows of memory cells within the memory array 220 and can support retrieval and storage of data in computer systems.

The buffer 250 temporarily stores data, such as signals received by or generated by the memory device 210. In some embodiments, the buffer 250 may facilitate transmission of signals between the memory device 210 and another memory device 210 or between the memory device 210 and a control circuit. The control circuit may be a logic circuit in a logic die. The buffer 250 can speed up signal transmission in embodiments where there is a relatively large distance (e.g., 1 micron or greater) between the memory device 210 and the other memory device 210 or between the memory device 210 and the control circuit.

In some embodiments, signals may pass through the buffer 250 before they arrive at the memory array 220. For example, a read request may be sent from a logic circuit, arrive at the memory device 210, then pass through the buffer 250 to the sense amplifier 260, the column decoder 240, the row decoder 230, the memory array 220, or some combination thereof. The read data may travel back from the memory array 220 to the logic circuit through the buffer 250. In an embodiment, the read request may be stored in the buffer temporarily before the read request is transmitted to the sense amplifier 260, the column decoder 240, the row decoder 230, or the memory array 220. Similarly, the read data may be stored in the buffer temporarily before the read data is transmitted to the control circuit.

The sense amplifier 260 may amplify and restore weak signals, e.g., to a more robust and usable level. In some embodiments, for reading data from the memory array 220, the sense amplifier 260 may detect and amplify the small voltage difference between the stored data states, typically representing binary values of 0 and 1. By amplifying this voltage difference, the sense amplifier 260 can enable accurate and reliable data retrieval. In some embodiments (e.g., embodiments having high speed data transmission), the sense amplifier 260 may amplify weak signals to avoid signal degradation and noise during signal propagation so that the signals can be more immune to noise, which can enable more accurate data recovery. The sense amplifier 260 may be a latch-based sense amplifier, differential sense amplifier, dynamic sense amplifier, or other types of sense amplifiers.

FIG. 3 illustrates an IC device 300 including a logic die 310 with a power interconnect 311 and a signal interconnect 312 for power and signal delivery and memory dies 320A and 320B over the logic die, according to some embodiments of the disclosure. The IC device 300 may also be referred to as an IC assembly. The memory dies 320A and 320B together may be referred to as memory dies 320. One of the memory dies 320A and 320B may be referred to as a memory die 320. As shown in FIG. 3, the IC device 300 further includes a conductive structures 360A-360C. In other embodiments, the IC device 300 may include fewer, more, or different components. For instance, the IC device 200 may include one or more other memory dies over the logic die 310.

In addition to the power interconnect 311 and signal interconnect 312, the logic die 310 further includes vias 313 (individually referred to as “via 313”), two capacitors 314 (individually referred to as “capacitor 314”), interconnects 315, 316, 317, and 318, two interposers 319 (individually referred to as “interposer 319”), a support structure 330, electrical insulator 340, and dielectric layers 350. In other embodiments, the logic die 310 may include fewer, more, or different components. Also, the components in the logic die 310 may be arranged differently.

The support structure 330 may be a semiconductor substrate composed of semiconductor material systems including, for example, N-type or P-type materials systems. In one implementation, the support structure 330 may be a crystalline substrate formed using a bulk silicon or a silicon-on-insulator (SOI) substructure. In other implementations, the support structure 330 may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of Group III-V materials (i.e., materials from groups III and V of the periodic table of elements), Group II-VI (i.e., materials from groups II and IV of the periodic table of elements), or Group IV materials (i.e., materials from Group IV of the periodic table of elements). In some embodiments, the support structure 330 may be non-crystalline. In some embodiments, the support structure 330 may be a printed circuit board (PCB) substrate. Although a few examples of materials from which the support structure 330 may be formed are described here, any material that may serve as a foundation upon which IC devices of the logic die 310 as described herein may be built falls within the spirit and scope of the present disclosure.

In some embodiments, the support structure 330 may be in a FEOL section of the logic die 310. The support structure 330 may include one or more semiconductor devices, such as transistors. The transistors may include field-effect transistor (FET), such as metal-oxide-semiconductor FET (MOSFET), tunnel FET (TFET), fin-based transistor (e.g., FinFET), nanoribbon-based transistor, nanowire-based transistor, gate-all-around (GAA) transistor, other types of FET, or a combination of both. In some embodiments, the support structure 330 may include one or more semiconductor structures. A semiconductor structure may be a non-planar structure, such as fin, nanoribbon, and so on.

The power interconnect 311 is a conductive structure, such as a metal line. The power interconnect 311 may facilitate power delivery to circuits or devices in the logic die 310 and the memory die 320. The power interconnect 311 may be, or otherwise be coupled to, a power plane. In some embodiments, the power interconnect 311 may be coupled to electrodes of transistors (e.g., electrodes over source regions or over drain regions of transistors) in the logic die 310 and the memory die 320. The power interconnect 311 may be at the same or similar electric potential as the electrodes during the operation of the logic die or the memory die 320.

The capacitors 314 are coupled to the power interconnect 311 to facilitate power delivery. Each capacitor includes conductive layers and dielectric layers. For the purpose of simplicity and illustration, the conductive layers are represented by solid black rectangles and the dielectric layers are represented by dot patterned rectangles in FIG. 3. A conductive layer of capacitor 314 on the left in FIG. 3 may be connected to the power interconnect 311. Another conductive layer of capacitor 314 on the left may be connected to a via 313. The via 313 may also be connected to a conductive layer of capacitor 314 on the right in FIG. 3.

The signal interconnect 312 is also a conductive structure, such as a metal line. The signal interconnect 312 may facilitate signal transmission between the logic die 310 and the memory die 320. The signal interconnect 312 may be coupled to electrodes of transistors (e.g., gate electrodes over channel regions of transistors) in the logic die 310 or the memory die 320. The signal interconnect 312 may be at the same or similar electric potential as the gate electrodes during the operation of the logic die or the memory die 320.

The interconnects 315, 316, 317, and 318 are also electrically conductive structures, e.g., metal lines, metal layers, etc. The power interconnect 311, signal interconnect 312, and interconnects 315, 316, 317, and 318 may be in a BEOL section of the logic die 310. The BEOL section may include a plurality of BEOL layers stacked over each other, such as a first BEOL layer including the two interconnects 318 (individually referred to as “interconnect 318”), a second BEOL layer including the interconnect 317, a third BEOL layer including the interconnect 316, a fourth BEOL layer including the three interconnects 315 (individually referred to as “interconnect 315”), and a sixth BEOL layer including the power interconnect 311 and signal interconnect 312.

The vias 313 facilitates electrical connections among the power interconnect 311, signal interconnect 312, and interconnects 315, 316, 317, and 318. A via 313 may be connected to one or more other vias 313 or to one or more interconnects (e.g., one or more of the power interconnect 311, signal interconnect 312, and interconnects 315, 316, 317, and 318). Some of the vias 313 may facilitate power delivery through the power interconnect 311. Some of the vias 313 may facilitate signal transmission from circuits or devices in the support structure 330 to the memory die 320 through the signal interconnect 312. Even though not shown in FIG. 3, the logic die 310 may include one or more vias that are connected to transistors in the support structure 330.

The interposers 319 facilitate electrical connection between the support structure 330 (e.g., transistor in the support structure 330) to components in the BEOL section of the logic die 310. An interposer 319 may include a semiconductor layer (e.g., a silicon layer) and a plurality of TSVs extending from a top surface of the semiconductor layer to the bottom surface of the semiconductor layer. The TSVs may be connected to one or more vias 313 and coupled to one or more interconnects in the BEOL section. In some embodiments, the interposers 319 may be in the FEOL section.

At least some of the conductive components of the logic die 310 (e.g., the power interconnect 311, signal interconnect 312, interconnects 315, 316, 317, and 318, vias 313, etc.) may be separated from each other by the electrical insulator 340. The dielectric layers 350 may also be insulative. In some embodiments, the dielectric layers 350 may be hard masks, which may facilitate formation of the at least some of conductive components of the logic die 310.

The memory dies 320 are over the logic die 310 along the Z axis. Each memory die 320 includes interconnects 321 and 322, vias 323 (individually referred to as “via 323”), two interposers 324 (individually referred to as “interposer 324”), a support structure 370, electrical insulator 380, and dielectric layers 390. In other embodiments, the memory die 320 may include fewer, more, or different components. Also, the components in the memory die 320 may be arranged differently.

The support structure 370 may be a semiconductor substrate composed of semiconductor material systems including, for example, N-type or P-type materials systems. In one implementation, the support structure 370 may be a crystalline substrate formed using a bulk SOI substructure. In other implementations, the support structure 370 may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of Group III-V materials (i.e., materials from groups III and V of the periodic table of elements), Group II-VI (i.e., materials from groups II and IV of the periodic table of elements), or Group IV materials (i.e., materials from Group IV of the periodic table of elements). In some embodiments, the support structure 370 may be non-crystalline. In some embodiments, the support structure 370 may be a PCB substrate. Although a few examples of materials from which the support structure 370 may be formed are described here, any material that may serve as a foundation upon which IC devices of the memory die 320 as described herein may be built falls within the spirit and scope of the present disclosure.

In some embodiments, the support structure 370 may be in a FEOL section of the memory die 320. The support structure 370 may include one or more semiconductor devices, such as transistors. The transistors may include FET, such as metal-oxide-semiconductor FET (MOSFET), tunnel FET (TFET), fin-based transistor (e.g., FinFET), nanoribbon-based transistor, nanowire-based transistor, GAA transistor, other types of FET, or a combination of both. In some embodiments, the support structure 370 may include one or more semiconductor structures. A semiconductor structure may be a non-planar structure, such as fin, nanoribbon, and so on.

The interconnects 321 and 322 and vias 323 are electrically conductive structures. The interconnects 321 and 322 may be metal lines. The interconnects 321 and 322 may be in a BEOL section of the memory die 320. For instance, the interconnects 321 and 322 may be in a BEOL metal layer. In some embodiments, the interconnect 321 or 322 may function as a bit line or word line of one or more memory arrays. A via 323 may be connected to one or more other vias 323 or to one or more interconnects. Even though not shown in FIG. 3, a memory die 320 may include one or more vias that are connected to transistors in the support structure 370.

The interposers 324 facilitate electrical connection between the support structure 330 (e.g., transistor in the support structure 330) to components in the BEOL section of the logic die 310. An interposer 324 may include a semiconductor layer (e.g., a silicon layer) and a plurality of TSVs extending from a top surface of the semiconductor layer to the bottom surface of the semiconductor layer. The TSVs may be connected to one or more vias 313 and coupled to one or more interconnects in the BEOL section. In some embodiments, the interposers 324 may be in the FEOL section.

At least some of the interconnects 321 and 322 and vias 323 may be separated from each other by the electrical insulator 380. The dielectric layers 390 may also be insulative. In some embodiments, the dielectric layers 390 may be hard masks, which may facilitate formation of the at least some of the interconnects 321 and 322 and vias 323.

In the embodiments of FIG. 3, the logic die 310 is coupled to the memory die 320A through the conductive structure 360A. A portion of the conductive structure 360A is between the logic die 310 and the memory die 320A. The conductive structure 360A may be connected to one or more components (e.g., transistors, etc.) in the support structure 330 and to one or more components (e.g., transistors, etc.) in the support structure 370. For instance, the conductive structure 360A may be connected to one or more electrodes of one or more transistors in a control circuit in the logic die 310 and to one or more electrodes of one or more transistors in the memory die 320A. In some embodiments, the conductive structure 360A may couple the control circuit to one or more bit lines or one or more word lines of one or more memory arrays (e.g., the memory array 120, the memory array 220, etc.) in the memory die 320A. Even though FIG. 3 shows a single conductive structure 360A, the IC device 300 may include more than one conductive structure that couples the logic die 310 to the memory die 320A. The IC device 300 may also be referred to as an IC device.

The conductive structure 360B couples the memory die 320A to the memory die 320B. In some embodiments, the conductive structure 360B has an end in the support structure 370. The end of the conductive structure 360B connected to one or more transistors in the support structure 370. The conductive structure 360B has another end connected to the interconnect 322 in the memory die 320A. The interconnect 322 in the memory die 320A is also connected to the conductive structure 360C. The conductive structure 360C is further connected to the interconnect 322 in the memory die 320B. The conductive structure 360C extends through the support structure 370 in the memory die 320B. The conductive structure 360C may be a TSV. In some embodiments, the conductive structure 360C may be connected or coupled to one or more transistors in the support structure 370.

In some embodiments, the interconnect 322 in each memory die 320 may be a global bit line (e.g., the global bit line 125G in FIG. 1) or a global word line (e.g., the global word line 223G in FIG. 1). The interconnect 322 in the memory die 320A is coupled to the interconnect 322 in the memory die 320B through the conductive structure 360C. In some embodiments, the interconnect 322 in the memory die 320B may be further coupled to an interconnect in another memory die, e.g., a memory die above the memory die 320B. In some embodiments, the interconnect 322 in the memory die 320A may be coupled to the interconnect 322 in the memory die 320B through one or more additional conductive structures.

The conductive structures 360A-360C may each have a longitudinal axis along the Z axis. The longitudinal axis may be perpendicular to the logic die 310 or each memory die 320. The conductive structures 360A-360C may facilitate delivery of power from the logic die 310 to the memory dies 320. The conductive structures 360A-360C may also facilitate delivery of signals between the logic die 310 and the memory dies 320 or between the memory dies 320. With the conductive structures 360A-360C, control circuits (e.g., peripheral circuits) or power delivery components may be avoided in the memory dies 320. Compared with currently available memory dies that includes peripheral circuits and peripheral circuits, more memory arrays may be arranged in an individual memory die and more memory dies 320 can be stacked in the same memory area.

Even though the memory dies 320 are above the logic die 310 in FIG. 3, one or both of the memory dies 320 or another memory die 320 may be below the logic die 310 in other embodiments. In the embodiments of FIG. 3, the memory die 320A and the logic die 310 has back-to-back attachment, i.e., the backside of the memory die 320A is attached to the backside of the logic die 310. In other embodiments, the memory die 320A and the logic die 310 may have front-to-front attachment (i.e., the frontside of the memory die 320A is attached to the frontside of the logic die 310), front-to-back attachment (i.e., the frontside of the memory die 320A is attached to the backside of the logic die 310), or back-to-front attachment (i.e., the backside of the memory die 320A is attached to the frontside of the logic die 310).

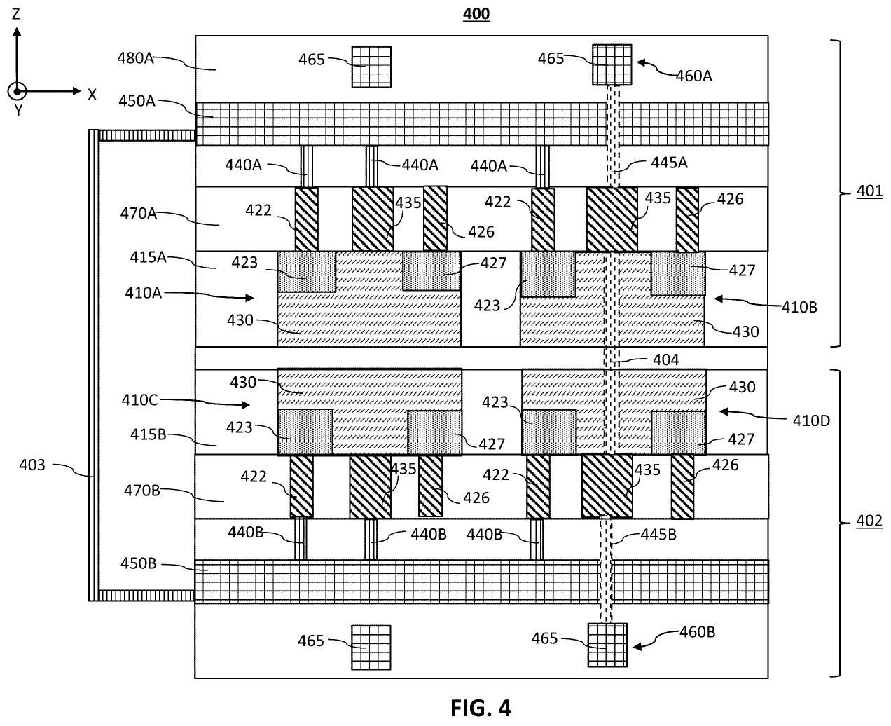

FIG. 4 illustrates an IC device 400 with transistors 410A-410D having global gate electrodes, according to some embodiments of the disclosure. The IC device 400 includes a memory device 401, another memory device 402, and conductive structures 403 and 404. The memory device 401 or 402 may be a portion of a memory array, such as the memory array 120 in FIG. 1 or the memory array 220 in FIG. 2. The memory device 401 includes the transistors 410A and 410B, a support structure 415A, vias 440A (individually referred to as “via 440A”), a via 445A, a metal layer 450A, another metal layer 460A, and electrical insulators 470A and 480A. The memory device 402 includes the transistors 410C and 410D a support structure 415B, vias 440B (individually referred to as “via 440B”), a via 445B, a metal layer 450B, another metal layer 460B, and electrical insulators 470B and 480B. In other embodiments, the IC device 400 may include fewer, more, or different components. For instance, the IC device 400 may include more transistors, or other semiconductor devices not shown in FIG. 4. Also, the IC device 400 may include a different number of metal layers, vias, or electrical insulators.

The transistors 410A-410D are collectively referred to as “transistors 410” or “transistor 410.” The support structures 415A and 415B are collectively referred to as “support structures 415” or “support structure 415.” The vias 440A and 440B are collectively referred to as “vias 440” or “via 440.” The vias 445A and 445B are collectively referred to as “vias 445” or “via 445.” The metal layers 450A and 450B are collectively referred to as “metal layers 450” or “metal layer 450.” The metal layers 460A and 460B are collectively referred to as “metal layers 460” or “metal layer 460.” The electrical insulators 470A and 470B are collectively referred to as “electrical insulators 470” or “electrical insulator 470.” The electrical insulators 480A and 480B are collectively referred to as “electrical insulators 480” or “electrical insulator 480.”

Each support structure 415 may be any suitable structure, such as a substrate, a die, a wafer, or a chip, based on which the transistors 410 can be built. In some embodiments, each support structure 415 may be a semiconductor substrate composed of semiconductor material systems including, for example, N-type or P-type materials systems, and, in some embodiments, the channel region 430, described herein, may be a part of the support structure 415. In some embodiments, the semiconductor substrate may be a crystalline substrate formed using a bulk SOI substructure. In other embodiments, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of Group III-V, Group II-VI, or Group IV materials. In some embodiments, the substrate may be non-crystalline. In some embodiments, the support structure may be a PCB substrate. One or more transistors, such as the transistors 410 may be built on the support structure 415.

Although a few examples of materials from which the support structure 415 may be formed are described here, any material that may serve as a foundation upon which an IC may be built falls within the spirit and scope of the present disclosure. In various embodiments, the support structure 415 may include any such substrate, possibly with some layers and/or devices already formed thereon, not specifically shown in the present figures. As used herein, the term “support” does not necessarily mean that it provides mechanical support for the IC devices/structures (e.g., transistors, capacitors, interconnects, and so on) built thereon. For example, some other structure (e.g., a carrier substrate or a package substrate) may provide such mechanical support and the support structure 415 may provide material “support” in that, e.g., the IC devices/structures described herein are build based on the semiconductor materials of the support structure 415. However, in some embodiments, the support structure 415 may provide mechanical support.

A transistor 410 may be an access transistor in a memory cell or a transistor in a control circuit associated with a memory cell. In some embodiments, a transistor 410 may be a FET, such as metal-oxide-semiconductor FET (MOSFET), tunnel FET (TFET), fin-based transistor (e.g., FinFET), nanoribbon-based transistor, nanowire-based transistor, GAA transistor, other types of FET, or a combination of both. The transistor 410 includes a semiconductor structure that includes a channel region 430, a source region 423, and a drain region 427. The transistor 410 includes a semiconductor structure that includes a channel region 430, a source region 423, and a drain region 427. The semiconductor structure of each transistor 410 may be at least partially in the support structure 415. The support structure 415 may include a semiconductor material, from which at least a portion of the semiconductor structure is formed. The semiconductor structure of a transistor 410 (or a portion of the semiconductor structure, e.g., the channel region 430) may be a planar structure or a non-planar structure. A non-planar structure is a three-dimensional structure, such as fin, nanowire, or nanoribbon. A non-planar structure may have a longitudinal axis and a transvers cross section perpendicular to the longitudinal axis. In some embodiments, a dimension of the non-planar structure along the longitudinal axis may be greater than dimensions along other directions, e.g., directions along axes perpendicular to the longitudinal axis.

Each channel region 430 includes a channel material. The channel material may be composed of semiconductor material systems including, for example, N-type or P-type materials systems. In some embodiments, the channel material may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the channel material may include a compound semiconductor with a first sub-lattice of at least one element from Group III of the periodic table (e.g., Al, Ga, In), and a second sub-lattice of at least one element of group V of the periodic table (e.g., P, As, Sb). In some embodiments, the channel material may include a compound semiconductor with a first sub-lattice of at least one element from Group II of the periodic table (e.g., Zn, Cd, Hg), and a second sub-lattice of at least one element of Group IV of the periodic table (e.g., C, Si, Ge, Sn, Pb). In some embodiments, the channel material is an epitaxial semiconductor material deposited using an epitaxial deposition process. The epitaxial semiconductor material may have a polycrystalline structure with a grain size between about 2 nm and 400 nm, including all values and ranges therein.

For some example N-type transistor embodiments (i.e., for the embodiments where the transistor 410 is an NMOS (N-type metal-oxide-semiconductor) transistor or an N-type TFET), the channel material may advantageously include a III-V material having a high electron mobility, such as, but not limited to InGaAs, InP, InSb, and InAs. For some such embodiments, the channel material may be a ternary III-V alloy, such as InGaAs, GaAsSb, InAsP, or InPSb. For some InxGa1-xAs fin embodiments, In content (x) may be between 0.6 and 0.9, and may advantageously be at least 0.7 (e.g., In0.7Ga0.3As). In some embodiments with highest mobility, the channel material may be an intrinsic III-V material, i.e., a III-V semiconductor material not intentionally doped with any electrically active impurity. In alternate embodiments, a nominal impurity dopant level may be present within the channel material, for example to further fine-tune a threshold voltage Vt, or to provide HALO pocket implants, etc. Even for impurity-doped embodiments however, impurity dopant level within the channel material 304 may be relatively low, for example below 4015 dopant atoms per cubic centimeter (cm⁻³), and advantageously below 40¹³ cm⁻³. These materials may be amorphous or polycrystalline, e.g., having a crystal grain size between 0.5 nanometers and 400 nanometers.

For some example P-type transistor embodiments (i.e., for the embodiments where the transistor 410 is a PMOS (P-type metal-oxide-semiconductor) transistor or a P-type TFET), the channel material may advantageously be a Group IV material having a high hole mobility, such as, but not limited to Ge or a Ge-rich SiGe alloy. For some example embodiments, the channel material may have a Ge content between 0.6 and 0.9, and advantageously may be at least 0.7. In some embodiments with highest mobility, the channel material may be intrinsic III-V (or IV for P-type devices) material and not intentionally doped with any electrically active impurity. In alternate embodiments, one or more a nominal impurity dopant level may be present within the channel material, for example to further set a threshold voltage (Vt), or to provide HALO pocket implants, etc. Even for impurity-doped embodiments however, impurity dopant level within the channel portion is relatively low, for example below 40¹⁵ cm⁻³, and advantageously below 40¹³ cm⁻³. These materials may be amorphous or polycrystalline, e.g., having a crystal grain size between 0.5 nanometers and 400 nanometers.

In some embodiments, the channel material may include a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, aluminum zinc oxide, or tungsten oxide. In general, for a thin-film transistor (TFT), the channel material may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, molybdenum disulfide, N- or P-type amorphous or polycrystalline silicon, monocrystalline silicon, germanium, indium arsenide, indium gallium arsenide, indium selenide, indium antimonide, zinc antimonide, antimony selenide, silicon germanium, gallium nitride, aluminum gallium nitride, indium phosphite, black phosphorus, zinc sulfide, indium sulfide, gallium sulfide, each of which may possibly be doped with one or more of gallium, indium, aluminum, fluorine, boron, phosphorus, arsenic, nitrogen, tantalum, tungsten, and magnesium, etc. In some embodiments, a thin-film channel material may be deposited at relatively low temperatures, which allows depositing the channel material within the thermal budgets imposed on back-end fabrication to avoid damaging other components, e.g., front-end components such as logic devices.

As noted above, the channel material may include IGZO. IGZO-based devices have several desirable electrical and manufacturing properties. IGZO has high electron mobility compared to other semiconductors, e.g., in the range of 20-50 times than amorphous silicon. Furthermore, amorphous IGZO (a-IGZO) transistors are typically characterized by high band gaps, low-temperature process compatibility, and low fabrication cost relative to other semiconductors.

IGZO can be deposited as a uniform amorphous phase while retaining higher carrier mobility than oxide semiconductors such as zinc oxide. Different formulations of IGZO include different ratios of indium oxide, gallium oxide, and zinc oxide. One particular form of IGZO has the chemical formula InGaO₃(ZnO)₅. Another example form of IGZO has an indium:gallium:zinc ratio of 4:2:1. In various other examples, IGZO may have a gallium to indium ratio of 4:1, a gallium to indium ratio greater than 4 (e.g., 2:1, 3:1, 4:1, 5:1, 6:1, 7:1, 8:1, 9:1, or 40:1), and/or a gallium to indium ratio less than 4 (e.g., 4:2, 4:3, 4:4, 4:5, 4:6, 4:7, 4:8, 4:9, or 4:10). IGZO can also contain tertiary dopants such as aluminum or nitrogen.

In each transistor 410, the source region 423 and the drain region 427 are connected to the channel region 430. The source region 423 and the drain region 427 each include a semiconductor material with dopants. In some embodiments, the source region 423 and the drain region 427 have the same semiconductor material, which may be the same as the channel material of the channel region 430. A semiconductor material of the source region 423 or the drain region 427 may be a Group IV material, a compound of Group IV materials, a Group III/V material, a compound of Group III/V materials, a Group II/VI material, a compound of Group II/VI materials, or other semiconductor materials. Example Group II materials include zinc (Zn), cadmium (Cd), and so on. Example Group III materials include aluminum (AI), boron (B), indium (In), gallium (Ga), and so on. Example Group IV materials include silicon (Si), germanium (Ge), carbon (C), etc. Example Group V materials include nitrogen (N), phosphorus (P), arsenic (As), antimony (Sb), and so on. Example Group VI materials include sulfur (S), selenium (Se), tellurium (Te), oxygen (O), and so on. A compound of Group IV materials can be a binary compound, such as SiC, SiGe, and so on. A compound of Group III/V materials can be a binary, tertiary, or quaternary compound, such as GaN, InN, and so on. A compound of Group II/VI materials can be a binary, tertiary, or quaternary compounds, such as CdSe, CdS, CdTe, ZnO, ZnSe, ZnS, ZnTe, CdZnTe, CZT, HgCdTe, HgZnTe, and so on.

In some embodiments, the dopants in the source region 423 and the drain region 427 are the same type. In other embodiments, the dopants of the source region 423 and the drain region 427 may be different (e.g., opposite) types. In an example, the source region 423 has N-type dopants and the drain region 427 has P-type dopants. In another example, the source region 423 has P-type dopants and the drain region 427 has N-type dopants. Example N-type dopants include Te, S, As, tin (Sn), Si, Ga, Se, S, In, Al, Cd, chlorine (CI), iodine (1), fluorine (F), and so on. Example P-type dopants include beryllium (Be), Zn, magnesium (Mg), Sn, P, Te, lithium (Li), sodium (Na), Ga, Cd, and so on.

In some embodiments, the source region 423 and the drain region 427 may be highly doped, e.g., with dopant concentrations of about 4.10²¹ cm⁻³, in order to advantageously form Ohmic contacts with the respective S/D contacts (also sometimes interchangeably referred to as “S/D electrodes”), although these regions may also have lower dopant concentrations and may form Schottky contacts in some implementations. Irrespective of the exact doping levels, the source region 423 and the drain region 427 may be the regions having dopant concentration higher than in other regions, e.g., higher than a dopant concentration in the channel region 430, and, therefore, may be referred to as “highly doped” (HD) regions.

The channel region 430 may include one or more semiconductor materials with doping concentrations significantly smaller than those of the source region 423 and the drain region 427. For example, in some embodiments, the channel material of the channel region 430 may be an intrinsic (e.g., undoped) semiconductor material or alloy, not intentionally doped with any electrically active impurity. In alternate embodiments, nominal impurity dopant levels may be present within the channel material, for example to set a threshold voltage Vt, or to provide HALO pocket implants, etc. In such impurity-doped embodiments however, impurity dopant level within the channel material is still significantly lower than the dopant level in the source region 423 and the drain region 427, for example below 40¹⁵ cm⁻³ or below 40¹³ cm⁻³. Depending on the context, the term “S/D terminal” may refer to a S/D region or a S/D contact or electrode of a transistor.

A transistor 410 also includes a source electrode 422 over the source region 423 and a drain electrode 426 over the drain region 427. The source electrode 422 is also referred to as a source electrode. The drain electrode 426 is also referred to as a drain electrode. The source electrodes 422 and the drain contacts 446 are electrically conductive and may be coupled to source and drain terminals for receiving electrical signals. A source electrode 422 or the drain electrode 426 includes one or more electrically conductive materials, such as metals. Examples of metals in the source electrodes 422 and the drain contacts 446 may include, but are not limited to, Ruthenium (Ru), copper (Cu), cobalt (Co), palladium (Pd), platinum (Pt), nickel (Ni), and so on.

In the embodiments of FIG. 4, the source electrode 422 of the transistor 410A may be separated from the source electrode 422 of the transistor 410C by one or more electrical insulators, e.g., the electrical insulators 470. The source electrode 422 of the transistor 410B may be separated from the source electrode 422 of the transistor 410D by one or more electrical insulators, e.g., the electrical insulators 470. The drain electrode 426 of the transistor 410A may be separated from the drain electrode 426 of the transistor 410C by one or more electrical insulators, e.g., the electrical insulators 470. The drain electrode 426 of the transistor 410B may be separated from the drain electrode 426 of the transistor 410D by one or more electrical insulators, e.g., the electrical insulators 470.

Each transistor 410 also includes a gate that is over or wraps around at least a portion of the channel region 430. The gate of the transistor 410 includes a gate electrode 435. The gate electrode 435 may also be referred to as a gate electrode. The gate of the transistor 410B includes a gate electrode 435. The gate electrode 435 can be coupled to a gate terminal that controls gate voltages applied on the transistor 410. In some embodiments, the gate electrode 435 may receive signals from a control circuit. The gate electrode may be coupled to a signal interconnect, such as the signal interconnect 312 in FIG. 3.

The gate electrode 435 may include one or more gate electrode materials, where the choice of the gate electrode materials may depend on whether the transistor 410 is a P-type transistor or an N-type transistor. For a P-type transistor, gate electrode materials that may be used in different portions of the gate electrode may include, but are not limited to, Ru, Pd, Pt, Co, Ni, and conductive metal oxides (e.g., ruthenium oxide). For an N-type transistor, gate electrode materials that may be used in different portions of the gate electrode, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode 435 may include a stack of a plurality of gate electrode materials, where zero or more materials of the stack are workfunction (WF) materials and at least one material of the stack is a fill metal layer. Further materials/layers may be included next to the gate electrode for other purposes, such as to act as a diffusion barrier layer or/and an adhesion layer.

In the embodiments of FIG. 4, the gate electrode 435 of each transistor 410 is a global gate electrode, i.e., the gate electrode 435 of each transistor 410 is coupled to the gate electrode 435 of another transistor 410. As shown in FIG. 4, the conductive structure 403 is connected to the metal layers 450A and 450B. The metal layer 450A is coupled to the gate electrode 435 of the transistor 410A through a via 440A, and the metal layer 450B is coupled to the gate electrode 435 of the transistor 410C through a via 440B. This way, these two gate electrodes 435 are coupled and may be at the same electrical potential(s) during the operation of the IC device 400. The conductive structure 403 may have a different location or shape in other embodiments. For instance, the conductive structure 403 may be straight between the metal layer 450A and 450B, as opposed to a U shape shown in FIG. 4. At least part of the conductive structure 403 is perpendicular to the metal layer 450A or 450B. The conductive structure 404 is connected to the gate electrode 435 of the transistor 410B and the gate electrode 435 of the transistor 410D so these two gate electrodes 435 are coupled and may be at the same electrical potential(s) during the operation of the IC device 400.

In some embodiments, each gate electrode 435 may be coupled to a word line, e.g., a word line 223 in FIG. 2. The two word lines corresponding to the gate electrode 435 of the transistor 410A and the gate electrode 435 of the transistor 410C are coupled through the two gate electrodes and the conductive structure 403. Similarly, the two word lines corresponding to the gate electrode 435 of the transistor 410B and the gate electrode 435 of the transistor 410D are coupled through the two gate electrodes and the conductive structure 404. These word lines are global word lines. In some embodiments, the transistor 410A and the transistor 410B may be in two memory cells, respectively, that are in the same row of a memory array, and the gate electrode 435 of the transistor 410A and the gate electrode 435 of the transistor 410B are coupled to the same word line. The transistor 410C and the transistor 410D may be in two memory cells, respectively, that are in the same row of another memory array, and the gate electrode 435 of the transistor 410C and the gate electrode 435 of the transistor 410D are coupled to the same word line.

The gate of each transistor 410 may also include a gate insulator (not show in FIG. 4) that separates at least a portion of the channel region 430 from the gate electrode so that the channel region 430 is insulated from the gate electrode. In some embodiments, the gate insulator may wrap around at least a portion of the channel region 430. The gate insulator may also wrap around at least a portion of the source region 423 or the drain region 427. At least a portion of the gate insulator may be wrapped around by the gate electrode. The gate insulator includes an electrical insulator, such as a dielectric material, hysteretic material, and so on. Example dielectric material includes oxide (e.g., Si based oxides, metal oxides, etc.), high-k dielectric, and so on. Example hysteretic material include ferroelectric materials, antiferroelectric materials, etc.

In the embodiments of FIG. 4, the metal layer 450 is the first metal layer at the frontside of the memory device 401 or 401. The metal layer 460 is the second metal layer at the frontside and is further from the transistor 410 than the metal layer 450. The metal layer 450 may be referred to as M0, and the metal layer 460 may be referred to as M1. Even though FIG. 4 shows a single metal line in the metal layer 450, the metal layer 450 may include one or more other metal lines. A metal line in the metal layer 450 may have a longitudinal axis along the X axis. The metal layer 460 includes metal lines 465, individually referred to as metal line 465. A metal line may be an electrically conductive structure. A metal line may also be referred to as a conductive line, a metal track, a conductive track, or an interconnect. In some embodiments, a metal line may include one or more metals, such as tungsten (W), molybdenum (Mo), ruthenium (Ru), copper (Cu), other metals, or some combination thereof. Metal lines are shown as rectangles in FIG. 4 for the purpose of simplicity and illustration. A metal line may have different shapes in other embodiments. A metal line may have a transvers cross section perpendicular to its longitudinal axis.

The metal layers 450 and 460 may be electrically coupled to the transistors 410. For instance, the metal layer 450 is coupled to the source electrodes 422 of the transistors 410 through the vias 440. Each via 440 has an end connected to the metal layer 450 and another end connected to a source electrode 422. The metal layer 460 is coupled to the gate electrodes 435 of the transistors 410 through the vias 445. Each via 445 has an end connected to a metal line 465 and another end connected to a gate electrode 435. In some embodiments, the metal layer 450 may facilitate operations of the transistors 410 by providing power to the transistors 410. The metal layer 460 may facilitate operations of the transistors 410 by providing signals to the transistors 410. In some embodiments, the metal layer 450 may function as bit line of a memory array, and the metal layer 460 may function as a word line of a memory array. A via 440 or 445 may include a metal, such as tungsten (W), molybdenum (Mo), ruthenium (Ru), copper (Cu), or other metals. In some embodiments, the IC device 400 may include one or more additional metal layers (not shown in FIG. 4) above the metal layer 460. The IC device 400 may include one or more additional vias connected to the one or more additional metal layer.

The electrical insulators 470 and 480 may separate conductive structures and semiconductor structures in the IC device 400 from each other so that they are shorted to each other. The electrical insulator 470 or 480 includes one or more electrically insulative materials. An electrically insulative material may be a dielectric material, hysteretic material, and so on. Example dielectric material includes oxide (e.g., Si based oxides, metal oxides, etc.), nitride (e.g., Si based nitride, etc.), low-k dielectric, high-k dielectric, and so on. Example hysteretic material include ferroelectric materials, antiferroelectric materials, and so on. In some embodiments, a portion of the electrical insulator 470 or 480 may include a first electrical insulator and a second electrical insulator with the second electrical insulator at least partially surrounding the first electrical insulator.

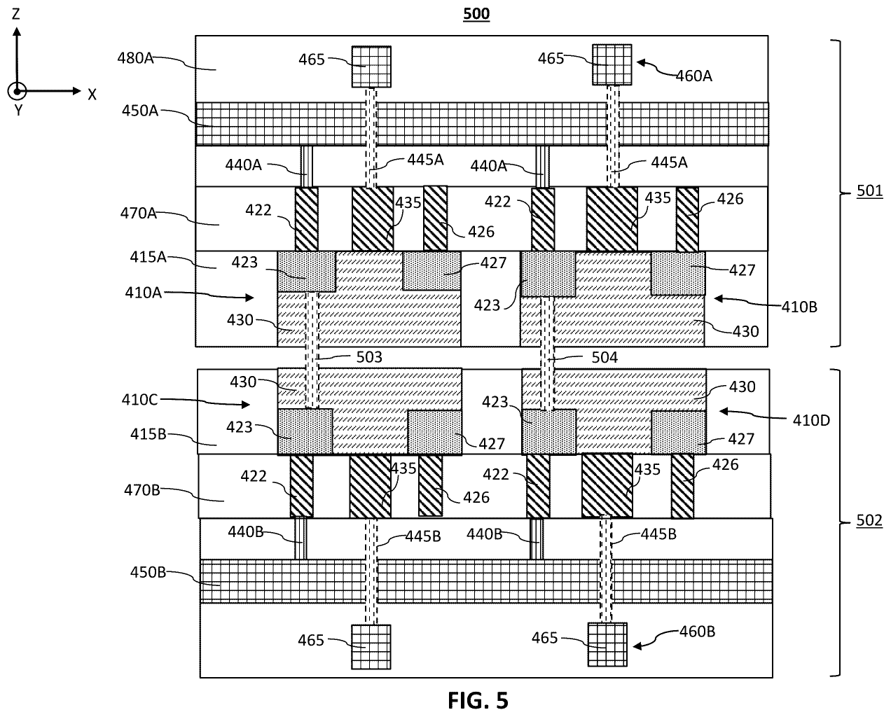

FIG. 5 illustrates an IC device 500 with transistors 410A-410D having global gate electrodes, according to some embodiments of the disclosure. The IC device 500 includes a memory device 501, another memory device 502, and conductive structures 503 and 504. The memory device 501 or 502 may be a portion of a memory array, such as the memory array 120 in FIG. 1 or the memory array 220 in FIG. 2. The memory device 501 may be the same or similar as the memory device 401 in FIG. 4. The memory device 502 may be the same or similar as the memory device 402 in FIG. 4. In other embodiments, the IC device 500 may include fewer, more, or different components.

Different from the IC device 400, the gate electrode 435 in the IC device 500 are not global gate electrodes. The gate electrode 435 of the transistor 410A is not coupled to the gate electrode 435 of the transistor 410C. The gate electrode 435 of the transistor 410A may be separated from the gate electrode 435 of the transistor 410C by one or more electrical insulators, e.g., the electrical insulators 470. The gate electrode 435 of the transistor 410B is not coupled to the gate electrode 435 of the transistor 410D. The gate electrode 435 of the transistor 410B may be separated from the gate electrode 435 of the transistor 410D by one or more electrical insulators, e.g., the electrical insulators 470.

In the embodiments of FIG. 5, the source electrodes 422 are global source electrode. The source electrode 422 of each transistor 410 is coupled to the source electrode 422 of another transistor 410. As shown in FIG. 5, the source electrode 422 of the transistor 410A is coupled to the source electrode 422 of the transistor 410C through the conductive structure 503, and the source electrode 422 of the transistor 410B is coupled t the source electrode 422 of the transistor 410D through the conductive structure 504. In other embodiments, the conductive structure 503 may be used to couple the drain electrode 426 of the transistor 410A is coupled to the drain electrode 426 of the transistor 410C. The conductive structure 504 may be used to couple the drain electrode 426 of the transistor 410B is coupled to the drain electrode 426 of the transistor 410D.

In some embodiments, each source electrode 422 (or each drain electrode 426) may be coupled to a bit line, e.g., a bit line 125 in FIG. 2. The two bit lines corresponding to the source electrode 422 (or the drain electrode 426) of the transistor 410A and the source electrode 422 (or the drain electrode 426) of the transistor 410C are coupled to each other through the two source electrodes 422 (or the two drain electrodes 426) and the conductive structure 503. Similarly, the two bit lines corresponding to the source electrode 422 (or the drain electrode 426) of the transistor 410B and the source electrode 422 (or the drain electrode 426) of the transistor 410D are coupled to each other through the two source electrodes 422 (or the two drain electrodes 426) and the conductive structure 504. These bit lines are global bit lines. In some embodiments, the transistor 410A and the transistor 410B may be in two memory cells, respectively, that are in the same column of a memory array, and the source electrode 422 of the transistor 410A and the source electrode 422 of the transistor 410B are coupled to the same bit line. The transistor 410C and the transistor 410D may be in two memory cells, respectively, that are in the same column of another memory array, and the source electrode 422 of the transistor 410C and the source electrode 422 of the transistor 410D are coupled to the same bit line.

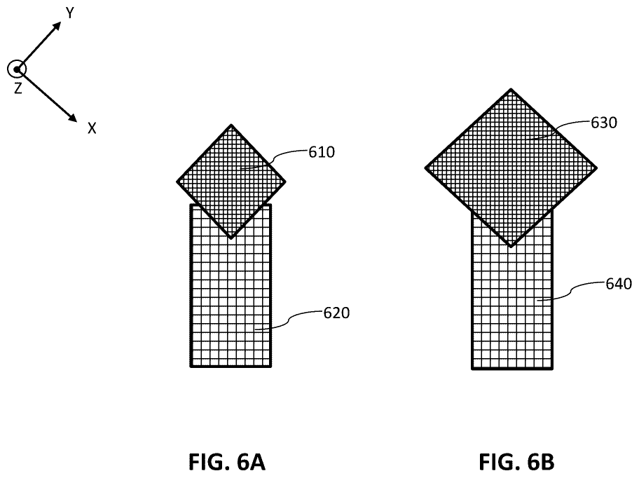

FIG. 6A illustrates semiconductor regions 610 and 620 of a transistor in a memory die, according to some embodiments of the disclosure. The transistor is also referred to as a memory transistor. The transistor may be an access transistor in a memory cell or a transistor in a peripheral circuit of the memory die. The memory transistor may be an embodiment of the transistors 410 in FIG. 4. FIG. 6B illustrates semiconductor regions 630 and 640 of a transistor in a logic die, according to some embodiments of the disclosure. The transistor is also referred to as a logic transistor. The logic transistor may be an embodiment of the transistors 410 in FIG. 4. For the purpose of illustration, FIGS. 6A and 6B do not show other components of the transistors.

As shown in FIG. 6A, the semiconductor region 610 wraps around a portion of the semiconductor region 620. The semiconductor region 610 may be a source region or drain region of the memory transistor. The semiconductor region 620 may be a channel region of the memory transistor. In some embodiments, the semiconductor region 610 (or a semiconductor structure including the semiconductor region 610) may be a non-planar structure, such as a fin or nanoribbon. The semiconductor region 610 can be formed over the semiconductor region 620 through an epitaxy process or a layer transfer process.

In FIG. 6B, the semiconductor region 630 wraps around a portion of the semiconductor region 640. The semiconductor region 630 may be a source region or drain region of the logic transistor. The semiconductor region 640 may be a channel region of the logic transistor. In some embodiments, the semiconductor region 630 (or a semiconductor structure including the semiconductor region 630) may be a non-planar structure, such as a fin or nanoribbon. The semiconductor region 630 can be formed over the semiconductor region 640 through an epitaxy process or a layer transfer process.

In some embodiments, the cross section of the semiconductor region 610 in the X-Y plane is smaller than the cross section of the semiconductor region 630 in the X-Y plane. A width of the semiconductor region 620 along the X axis may be approximately 5% to approximately 50% larger than the width of the semiconductor region 610 along the X axis. For purpose of illustration, the cross section of the semiconductor region 610 in FIG. 6A and the cross section of the semiconductor region 630 in FIG. 6A each has a shape of a parallelogram with sharp corners. In other embodiments, the cross section of the semiconductor region 610 or the semiconductor region 630 can have other shapes, e.g., a curved shape with round corners.

In some embodiments, a transistor in a logic die may have more (e.g., approximately one to three times more) nanoribbon structures than a transistor in a memory die. The shape of the semiconductor region 610 may be different from the shape of the semiconductor region 620 in some embodiments. For instance, the semiconductor region 610 may be a fin, while the semiconductor region 620 may be a nanoribbon or nanowire.

FIG. 7 illustrates an IC device 700 including a stack of wafers, according to some embodiments of the disclosure. The IC device 700 may also be referred to as an IC assembly. The stack of wafers includes wafers 712 (individually referred to as “wafer 712”) and a wafer 714, which may be bonded to one another by hybrid bonding. The wafers 712 may include transistors forming memory cells to implement memory arrays of the IC device 700, while the wafer 714 may include transistors forming control logic configured to control operation of (e.g., to control input/output or read/write to) the memory arrays of the memory cells of the wafers 712. The wafers 712 may be referred to as “memory wafers.” The wafer 714 may be referred to as a “logic wafer,” “compute wafer,” or “compute logic wafer.” In some embodiments, the wafer 714 may include logic circuits used to control the wafers 712—like I/O, memory scheduler etc.

Each of the wafers 712 and 714 of the IC device 700 may be composed of one or more semiconductor materials and may include one or more dies having IC structures formed on a surface of the wafers 712 and 714. As shown in FIG. 7, each wafer 712 includes a plurality of memory dies 720 (individually referred to as “memory die 720”). A memory die 720 may be referred to as a “memory chiplet.” An embodiment of a memory die 720 may be the memory die 320A or 320B in FIG. 3. The wafer 714 includes a plurality of logic dies 730 (individually referred to as “logic die 730”). A logic die 730 may be referred to as a “compute chiplet.” An embodiment of a logic die 730 may be the logic die 310 in FIG. 3.

Each memory die 720 or logic die 310 may be a repeating unit of a semiconductor product that includes any suitable IC, e.g., an IC implementing memory, an IC implementing compute logic, etc. After the fabrication of the semiconductor product is complete, the wafers 712 and 714 may undergo a singulation process in which the memory dies 720 and the logic dies 730 are separated from one another to provide discrete “chips” of the semiconductor product.

Each memory die 720 includes a plurality of memory devices 725. Examples of the memory devices 725 include the memory device 110 in FIG. 1 and the memory device 210 in FIG. 2. Each memory device 725 may include a memory array. A memory die 720 may include no peripheral circuits so that the number of memory arrays that can be arranged in the memory die 720 can be maximized. Even though FIG. 7 shows three wafers 712, the IC device 700 may include a different number of wafers 712.

The memory devices 725 may be controlled by one or more logic circuits in the logic die 730. Also, the logic die 730 may include, or otherwise be associated with, power delivery components for delivering power to the memory devices 725. For instance, the logic die 730 may include one or more power interconnects, one or more power vias, etc. The logic die 730 may transmit signals to the memory devices 725 for reading data from the memory devices 725 or writing data into the memory devices 725. In some embodiments, the logic die 730 may include one or more processing units (e.g., central processing unit (CPU), graphics processing unit (GPU), etc.) that can generate data read or write signals, generate data to be written into memory cells in the memory layers 110, process data read from memory cells in the memory layers 110, and so on.

Some or all of the memory devices 725 may include global bit lines or global word lines so that rows or columns of memory cells in different memory dies 720 may be controlled with the same signal. In some embodiments, global bit lines may be implemented by using conductive structures connected to bit lines in memory devices 725. Similarly, global word lines may be implemented by using conductive structures connected to word lines in memory devices 725. In other embodiments, global bit lines may be implemented by using conductive structures connected to source electrodes or drain electrodes of transistor in memory devices 725. Global word lines may be implemented by using conductive structures connected to gate electrodes of transistor in memory devices 725.

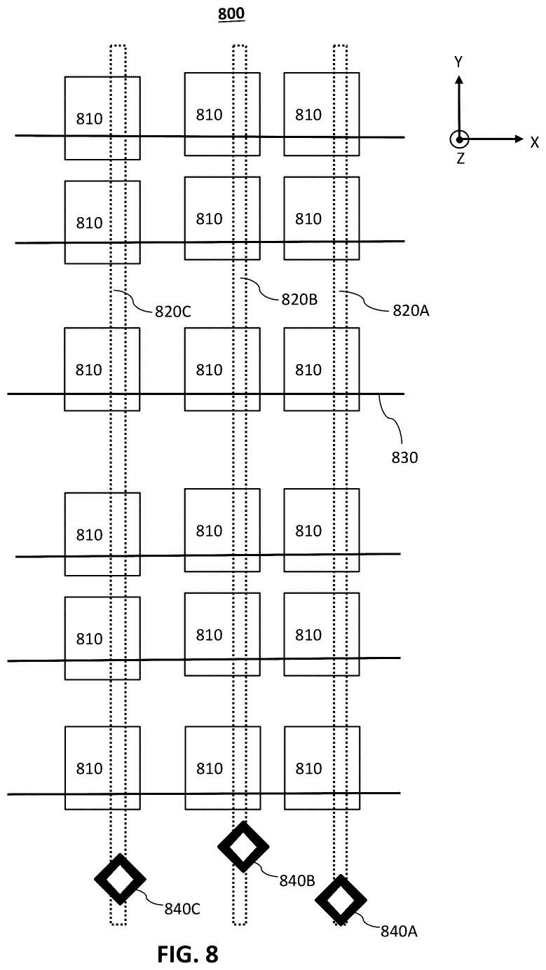

FIG. 8 illustrates a stack of memory arrays 800, each of which include global bit lines 820A-820C, according to some embodiments of the present disclosure. The memory arrays 800 (individually referred to as a “memory array 800”) are stacked along the Z axis. As shown in FIG. 8, a memory array 800 includes 18 memory cells 810 (individually referred to as a “memory cell 810”) that are arranged in 3 columns and 6 rows. In other embodiments, a memory array 800 may include a different number of memory cells 810, a different number of columns, or a different number of rows. The memory array 800 may be an example of a memory array 120 in FIG. 1 or an example of a memory array 220 in FIG. 2.

In the embodiments of FIG. 8, the memory cells 810 in each column are coupled to one of the global bit lines 820A-830C. The memory cells 810 in each row are coupled to a word line 830. The global bit lines 820A-830C are coupled to conductive structures 840A-840C, respectively. For instance, the global bit line 820A may be connected to the conductive structure 840A, the global bit line 820B may be connected to the conductive structure 840B, and the global bit line 820C may be connected to the conductive structure 840C. Each of the conductive structures 840A-840C may be connected to one or more other global bit lines in one or more other memory arrays 800 in the stack. Each of the conductive structures 840A-840C may have a zigzag pattern in the X-Y plane, e.g., around the Y axis.

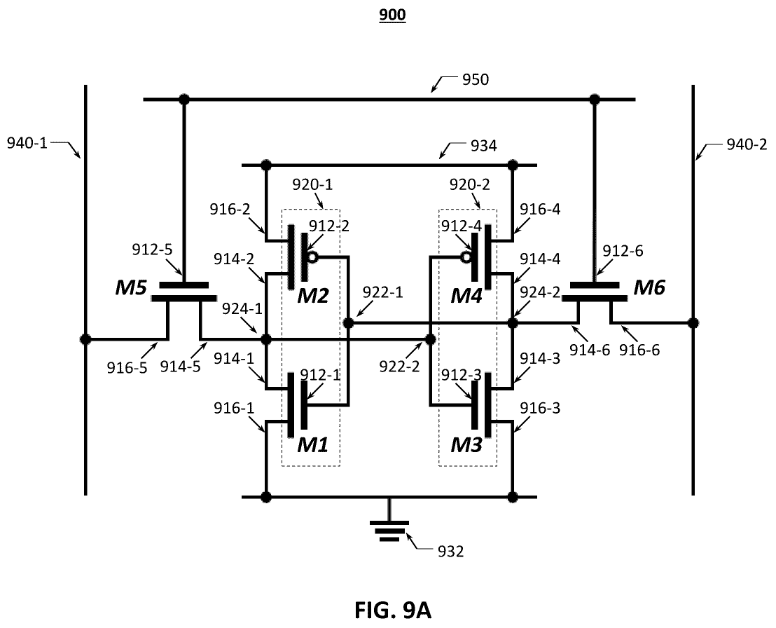

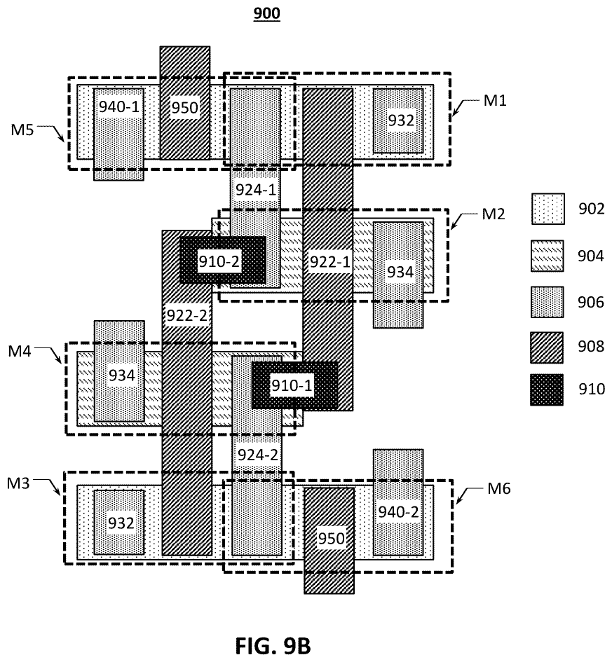

FIG. 9A is an electric circuit diagram of an example memory cell 900, according to some embodiments of the present disclosure. The memory cell 900 may be in a memory array, e.g., the memory array 120 in FIG. 1 or the memory array 220 in FIG. 2. In some embodiments, the memory cell 900 may be an SRAM cell used in an SRAM array. As shown in FIG. 9B, the memory cell 900 includes transistors M1-M4 for storing a bit value or a memory state (e.g., logic “1” or “0”) of the cell, and two access transistors, M5 and M6, for controlling access to the cell (e.g., access to write information to the cell or access to read information from the memory cell 900). The memory cell 900 is a 6-transistor (6T) memory cell. In other embodiments, the memory cell 900 may include a different number of transistors. Each of the transistors M1-M6 may have any transistor architecture (e.g., planar or non-planar, FinFET, nanoribbon/nanowire, etc.). For example, the transistors M1-M6 may have the transistor architecture shown in FIG. 4. An example of the transistors M1-M6 may be one of the transistors 410 in FIG. 4.

In the memory cell 900, each bit may be stored on four transistors (M1, M2, M3, M4) that form two cross-coupled inverters 920, each having an input 922 and an output 924. The first inverter 920-1 may be formed by an NMOS transistor M1 and a PMOS transistor M2, while the second inverter 920-2 may be formed by an NMOS transistor M3 and a PMOS transistor M4. As shown in FIG. 9B, the gate stack 912-1 of the transistor M1 may be coupled to the gate stack 912-2 of the transistor M2, and both of these gate stacks may be coupled to the input 922-1 of the first inverter 920-1. On the other hand, the first S/D region 914-1 of the transistor M1 may be coupled to the first S/D region 914-2 of the transistor M2, and both of these first S/D regions 914-1 and 914-2 may be coupled to the output 924-1 of the first inverter 920-1. Similarly, for the second inverter 320-2, the gate stack 912-3 of the transistor M3 may be coupled to the gate stack 912-4 of the transistor M4, and both of these gate stacks may be coupled to the input 922-2 of the second inverter 920-2, while the first S/D region 914-3 of the transistor M3 may be coupled to the first S/D region 914-4 of the transistor M4, and both of these first S/D regions 914-3 and 914-4 may be coupled to the output 924-2 of the second inverter 920-2. As also shown in FIG. 9B, when the transistors M1 and M3 are NMOS transistors and when the transistors M2 and M4 are PMOS transistors as illustrated in FIG. 9B, the second S/D regions 916-1 and 916-3 of the transistors M1 and M3 may be coupled to a ground voltage 932, while the second S/D regions 916-2 and 916-4 of the transistors M2 and M4 may be coupled to a supply voltage 934, e.g., VDD. In the embodiments of the memory cell 900 where the NMOS transistors shown in FIG. 9B are replaced with PMOS transistors and vice versa, the designation of the ground voltage 932 and the supply voltage 934 would be reversed as well, all of which embodiments being within the scope of the present disclosure.

The four transistors M1-M4 in such configuration form a stable storage cell for storing a bit value of 0 or 1. As further shown in FIG. 9B, two additional access transistors, M5 an M6, may serve to control the access to the storage cell of the transistors M1-M4 during read and write operations. As shown in FIG. 9B, the first S/D region 914-5 of the access transistor M5 may be coupled to the output 924-1 of the first inverter 920-1. Phrased differently, the first S/D region 914-5 of the access transistor M5 may be coupled to each of the first S/D region 914-1 of the transistor M1 and the first S/D region 914-2 of the transistor M2. The second S/D region 916-5 of the access transistor M5 may be coupled to a first bit line 940-1. Thus, each of the first S/D region 914-1 of the transistor M1 and the first S/D region 914-2 of the transistor M2 may be coupled to the first bit line 940-1 (e.g., via the access transistor M5). The gate 912-5 of the access transistor M5 may be coupled to a word line 950.

As further shown in FIG. 9B, the first S/D region 914-6 of the access transistor M6 may be coupled to the output 924-2 of the second inverter 920-2. Phrased differently, the first S/D region 914-6 of the access transistor M6 may be coupled to each of the first S/D region 914-3 of the transistor M3 and the first S/D region 914-4 of the transistor M4. The second S/D region 916-6 of the access transistor M6 may be coupled to a second bit line 940-2. Thus, each of the first S/D region 914-3 of the transistor M3 and the first S/D region 914-4 of the transistor M4 may be coupled to the second bit line 940-2 (e.g., via the access transistor M6). The gate 912-6 of the access transistor M6 may be coupled to the word line 950. Thus, the gates 912-5 and 912-6 of both of the access transistors M5 and M6 may be coupled to a single, shared, WL, the word line 950.

As also shown in FIG. 9B, the input 922-1 of the first inverter 920-1 may be coupled to the first S/D region 914-6 of the access transistor M6, while the input 922-2 of the second inverter 920-2 may be coupled to the first S/D region 914-5 of the access transistor M5. In other words, each of the gate stack 912-1 of the transistor M1 and the gate stack 912-2 of the transistor M2 may be coupled to the first S/D region 914-6 of the access transistor M6, while each of the gate stack 912-3 of the transistor M3 and the gate stack 912-4 of the transistor M4 may be coupled to the first S/D region 914-5 of the access transistor M5. Phrased differently, each of the gate stack 912-1 of the transistor M1 and the gate stack 912-2 of the transistor M2 may be coupled to the second bit line 940-2 (e.g., via the access transistor M6), while each of the gate stack 912-3 of the transistor M3 and the gate stack 912-4 of the transistor M4 may be coupled to the first bit line 940-1 (e.g., via the access transistor M5).

The word line 950 and the first and second bit lines 940 may be used together to read and program (i.e., write to) the memory cell 900. In particular, access to the cell may be enabled by the word line 950 which controls the two access transistors M5 and M6 which, in turn, control whether the memory cell 900 should be connected to the bit lines 940-1 and 940-2. During operation of the memory cell 900, a signal on the first bit line 940-1 may be complementary to a signal on the second bit line 940-2. The two bit lines 940 may be used to transfer data for both read and write operations. In other embodiments of the memory cell 900, only a single bit line 940 may be used, instead of two bitlines 940-1 and 940-2, although having one signal bit line and one inverse, such as the two bit lines 940, may help improve noise margins.

During read accesses, the bit lines 940 are actively driven high and low by the inverters 920 in the memory cell 900. This may improve SRAM bandwidth compared to DRAM. The symmetric structure of the memory cell 900 also allows for differential signaling, which may provide an improvement in detecting small voltage swings. Another difference with DRAM that may contribute to making SRAM faster than DRAM is that commercial chips accept all address bits at a time. By comparison, commodity DRAMs may have the address multiplexed in two halves, i.e. higher bits followed by lower bits, over the same package pins in order to keep their size and cost down.

Each of the word line 950 and the bit lines 940, as well as intermediate elements coupling these lines to various terminals described herein, may be formed of any suitable electrically conductive material, which may include an alloy or a stack of multiple electrically conductive materials. In some embodiments, such electrically conductive materials may include one or more metals or metal alloys, with metals such as ruthenium, palladium, platinum, cobalt, nickel, hafnium, zirconium, titanium, tantalum, and aluminum. In some embodiments, such electrically conductive materials may include one or more electrically conductive alloys oxides or carbides of one or more metals.

FIG. 9B provides a top-down plan view of one example implementation of a 6T memory cell, according to some embodiments of the present disclosure. FIG. 9B illustrates how the six transistors M1-M6 shown in FIG. 9B may be implemented. Several elements from FIG. 9B are labelled in FIG. 9B. For example, the transistors M1-M6 are labelled in FIG. 9B, with the approximate boundaries of the individual transistors shown in FIG. 9B with dashed rectangles. Certain elements, e.g., the specific S/D regions 914 and 916 and the gate stacks 912, are not labelled in FIG. 9B in order to not clutter the drawings.

FIG. 9B illustrates that transistors M1 and M5 may be provided along a first region of an N-type semiconductor 902, transistors M2 and M4 may each be provided along a respective first and second region of a P-type semiconductor 904, and the transistors M4 and M6 may be provided along a second region of the N-type semiconductor 902. Each of the regions of the N-type semiconductor 902 and P-type semiconductor 904 may be formed in a support structure (e.g., a substrate) or over a support structure, e.g., as a fin or nanoribbon. The N-type semiconductor 902 is suitable for forming transistors of a first type, e.g., NMOS transistors, while the P-type semiconductor 904 is suitable for forming transistors of a second type, e.g., PMOS transistors, thus realizing NMOS transistors M1, M3, M5, and M6, and PMOS transistors M2 and M4, as shown in FIG. 9B.

In the plan view shown in FIG. 9B, S/D contacts 906, gate electrodes 908, and interconnects 910 are formed over the N-type and P-type semiconductors 902 and 904, e.g., as layers processed over the N-type and P-type semiconductors 902 and 904. While not specifically shown in FIG. 9B, S/D regions may be formed under the S/D contacts 906, and gate dielectrics may be formed under the gate electrodes 908. Any of the materials and processes described with respect to FIG. 4 may be used to form the transistors shown in FIG. 9B.

More specifically, a shared gate stack may be used to realize the gate stack 912-1 of the transistor M1 coupled to the gate stack 912-2 of the transistor M2. The shared gate stack is labelled 922-1 in FIG. 9B, representing a node that is the input 922-1 of the first inverter 920-1 of the memory cell 900. Similarly, a shared gate stack may be used to realize the gate stack 212-3 of the transistor M3 coupled to the gate stack 212-4 of the transistor M4 3. The shared gate stack is labelled 922-2 in FIG. 9B, representing a node that is the input 922-2 of the second inverter 920-2 of the memory cell 900.

As also shown in FIG. 9B, a first shared S/D contact may be used to realize the first S/D region 914-1 of the transistor M1 coupled to the first S/D region 914-2 of the transistor M2. The first shared S/D contact is labelled 924-1 in FIG. 9B, representing a node that is the output 924-1 of the first inverter 920-1 of the memory cell 900. Similarly, a second shared S/D contact may be used to realize the first S/D region 914-3 of the transistor M3 coupled to the first S/D region 914-4 of the transistor M4. The first shared S/D contact is labelled 924-2 in FIG. 9B, representing a node that is the output 924-2 of the second inverter 920-2 of the memory cell 900.

A first interconnect 910-1, shown in FIG. 9B, may then be used to couple the shared gate stack 922-1 of the first inverter 920-1 to the shared S/D contact 924-2 of the second inverter 920-2, thus realizing the coupling of the input 922-1 of the first inverter 920-1 to the output 924-2 of the second inverter 920-2, shown in FIG. 9B. Similarly, a second interconnect 910-2, shown in FIG. 9B, may then be used to couple the shared gate stack 922-2 of the second inverter 920-2 to the shared interconnect 924-1 of the first inverter 920-1, thus realizing the coupling of the input 922-2 of the second inverter 920-2 to the output 924-1 of the first inverter 920-1, shown in FIG. 9B.

FIG. 9B further illustrates that, in a given memory cell 900, the first S/D region 914-5 of the transistor M5 may be shared with (e.g., be the same as) the first S/D region 914-1 of the transistor M1 (since both of these transistors are implemented in a single region of the N-type semiconductor 902). In addition, the first S/D region 914-3 of the transistor M3 may be shared with (e.g., be the same as) the first S/D region 914-6 of the transistor M6 (since both of these transistors are implemented in a single region of the N-type semiconductor 902).

Both of the second S/D region 916-1 of the transistor M1 and the second S/D region 916-3 of the transistor M3 may be coupled to the ground voltage 932, as was described with reference to FIG. 9B. Both of the second S/D region 916-2 of the transistor M2 and the second S/D region 916-4 of the transistor M4 may be coupled to the supply voltage 934, as was described with reference to FIG. 9B.

FIG. 10 is an IC device 1000 with memory layers 1010A-1010D sharing word line drivers 1030 in a CMOS layer, according to some embodiments of the disclosure. In the embodiments of FIG. 10, the CMOS layer is between the memory layers 1010B and 1010C, so that the memory layers 1010A and 1010B are at the frontside of the CMOS layer versus the memory layers 1010C and 1010D are at the backside of the CMOS layer. The four memory layers 1010A-1010D may be referred to as “memory layers 1010” or “memory layer 1010.” In other embodiments, the IC device 1000 may include a different number of memory layers at either side of the CMOS layer. For the purpose of illustration, the CMOS layer is not shown in FIG. 10. Also, the IC device 1000 may include other components that are not shown in FIG. 10, such as bonding layers, vias, and so on. The IC device 1200 may also be referred to as an IC assembly.

The CMOS layer provides power and signals to the memory layers 1010. The CMOS layer may also receive signals (e.g., data stored in the memory layers 1010) from the memory layers 1010. The CMOS layer may be an example of the logic layer 310 in FIG. 3. In the embodiments of FIG. 10, the CMOS layer includes four word line drivers 1030 (individually referred to as “word line driver 1030”) and three sense amplifiers 1040 (individually referred to as “sense amplifier 1040”). Even though not shown in FIG. 10, the CMOS layer may include other components, such as row decoders, column decoders, SRAM arrays, and so on. The word line drivers 1030 may be separate from each other. In some embodiments, the word line drivers 1030 are separated from each other by one or more electrical insulators. The sense amplifiers 1040 may also be separate from each other. In some embodiments, the sense amplifiers 1040 are separated from each other by one or more electrical insulators.

Each memory layer 1010 includes word lines 1013 (individually referred to as “word line 1013”) and bit lines 1017 (individually referred to as “word line 1013”). Each memory layer 1010 may also include memory cells coupled to the word lines 1013 and bit lines 1017. The memory layers 1010 may be examples of the memory dies 320 in FIG. 3. In some embodiments, the word lines 1013 are coupled to the word line drivers 1030 in the CMOS layer, and the bit lines 1017 are coupled to the sense amplifiers 1040 in the CMOS layer.

For the purpose of simplicity and illustration, FIG. 10 shows connections between representative word lines 1013A-1013L and the word line drivers 1030 and connections between representative bit lines 1017A-1017D and sense amplifiers 1040. The IC device 1000 may include other connections between word lines 1013 and word line drivers 1030 or other connections between bit lines 1017 and sense amplifiers 1040. As shown in FIG. 10, the word lines 1013A, 1013E, and 1013I and bit line 1017A are in the memory layer 1010A; the word lines 1013B, 1013F, and 1013J and bit line 1017B are in the memory layer 1010B; the word lines 1013C, 1013G, and 1013K and bit line 1017C are in the memory layer 1010C; and the word lines 1013D, 1013H, and 1013L and bit line 1017D are in the memory layer 1010D.

The word lines 1013A-1013D (i.e., a first word line group) share a first one of the word line drivers 1030. The word lines 1013E-1013H (i.e., a second word line group) share a second one of the word line drivers 1030. The word lines 1013I-1013L (i.e., a third word line group) share a third one of the word line drivers 1030. Each of the four word line groups are coupled to the word line driver 1030 through a conductive structure 1035. The conductive structure 1035 is connected to the four word lines 1013 in the word line group and to the word line driver 1030. The four word lines 1013 in the same word line group may be activated by the same signal form the word line driver 1030.

The four bit lines 1017A-1017D are coupled to the four sense amplifiers 1040, respectively, through conductive structures 1045 (individually referred to as “conductive structure 1045”). Each conductive structure 1045 is connected to one of the bitlines 1017A-1017D and a sense amplifier 1040. conductive structure 1035 or 1045 may extend in a direction perpendicular to the memory layers 1010. Each conductive structure 1035 or 1045 may include one or more vias, including TSVs. In some embodiments, the sense amplifiers 1040 are multiplexed. The bit lines 1017A-1017D do not share sense amplifiers 1040 with each other and can be activated separately. Even though word lines 1013 in different memory layers 1010 are coupled, the separation of bit lines 1017 in different memory layers 1010 can facilitate independent controls of memory cells in the memory layers 1010. Memory cells in different memory layers 1010 may have different memory addresses, based on which the memory cells may be located, selected, or accessed.

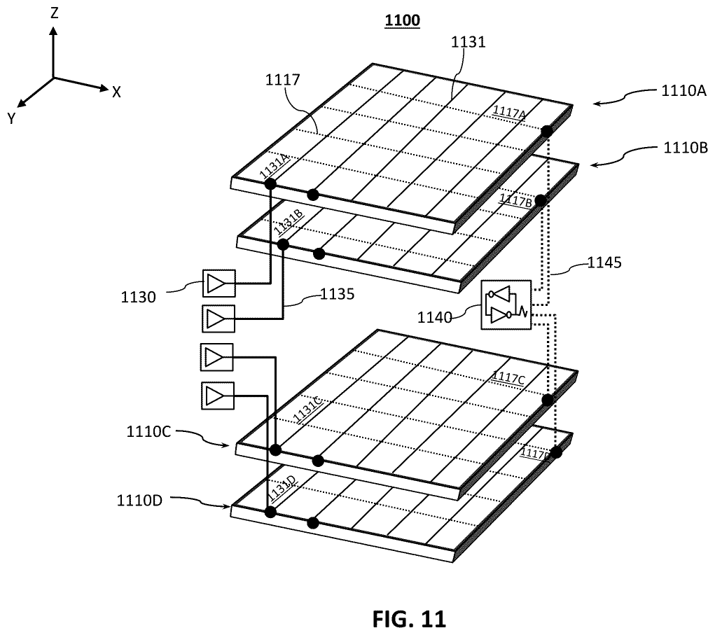

FIG. 11 illustrates an IC device 1100 with memory layers 1110A-1110D sharing sense amplifiers in a CMOS layer, according to some embodiments of the disclosure. In the embodiments of FIG. 11, the CMOS layer is between the memory layers 1110B and 1110C, so that the memory layers 1110A and 1110B are at the frontside of the CMOS layer versus the memory layers 1110C and 1110D are at the backside of the CMOS layer. The four memory layers 1110A-210D may be referred to as “memory layers 1110” or “memory layer 1110.” In other embodiments, the IC device 1100 may include a different number of memory layers at either side of the CMOS layer. For the purpose of illustration, the CMOS layer is not shown in FIG. 11. Also, the IC device 1100 may include other components that are not shown in FIG. 11, such as bonding layers, vias, and so on. The IC device 1100 may also be referred to as an IC assembly.

The CMOS layer provides power and signals to the memory layers 1110. The CMOS layer may also receive signals (e.g., data stored in the memory layers 1110) from the memory layers 1110. The CMOS layer may be an example of the logic die 310 in FIG. 3. In the embodiments of FIG. 11, the CMOS layer includes four word line drivers 1130 (individually referred to as “word line driver 1130”) and a sense amplifier 1140. Even though not shown in FIG. 11, the CMOS layer may include other components, such as additional word line driver 1130, additional sense amplifier 1140, row decoders, column decoders, SRAM arrays, and so on. The word line drivers 1130 may be separate from each other. In some embodiments, the word line drivers 1130 are separated from each other by one or more electrical insulators.

Each memory layer 1110 includes word lines 1113 (individually referred to as “word line 1113”) and bit lines 1117 (individually referred to as “word line 1113”). Each memory layer 1110 may also include memory cells coupled to the word lines 1113 and bit lines 1117. The memory layers 1110 may be examples of the memory dies 320 in FIG. 3. In some embodiments, the word lines 1113 are coupled to the word line drivers 1130 in the CMOS layer, and the bit lines 1117 are coupled to the sense amplifiers 1140 in the CMOS layer.

For the purpose of simplicity and illustration, FIG. 11 shows connections between representative word lines 1113A-1113D and the word line drivers 1130 and connections between representative bit lines 1117A-1117D and sense amplifier 1140. The IC device 1100 may include other connections between word lines 1113 and word line drivers 1130 or other connections between bit lines 1117 and sense amplifier 1140. As shown in FIG. 11, the word line 1113A and bit line 1117A are in the memory layer 1110A; the word line 1113B and bit line 1117B are in the memory layer 1110B; the word line 1113C and bit line 1117C are in the memory layer 1110C; and the word line 1113D and bit line 1117D are in the memory layer 1110D.

The four word lines 1113A-1113D are coupled to the four word line drivers 1130, respectively, through four conductive structures 1135 (individually referred to as “conductive structure 1135”). Each conductive structure 1135 is connected to one of the word lines 1113A-1113D and one of the word line drivers 1130. The word lines 1113A-1113D do not share word line drivers 1130 with each other and can be activated separately. The bit lines 1117A-1117D share the sense amplifier 1140. As shown in FIG. 11, the bit lines 1117A-1117D are all coupled to the sense amplifier 1140 through conductive structures 1145 (individually referred to as “conductive structure 1145”). Each conductive structure 1145 is connected to one of the bit lines 1117A-1117D and the sense amplifier 1140. A conductive structure 1135 or 1145 may extend in a direction perpendicular to the memory layers 1110. Each conductive structure 1135 or 1145 may include one or more vias, including TSVs. Even though bit lines 1117 in different memory layers 1110 are coupled, the separation of word lines 1113 in different memory layers 1110 can facilitate independent controls of memory cells in the memory layers 1110. Memory cells in different memory layers 1110 may have different memory addresses, based on which the memory cells may be located, selected, or accessed.

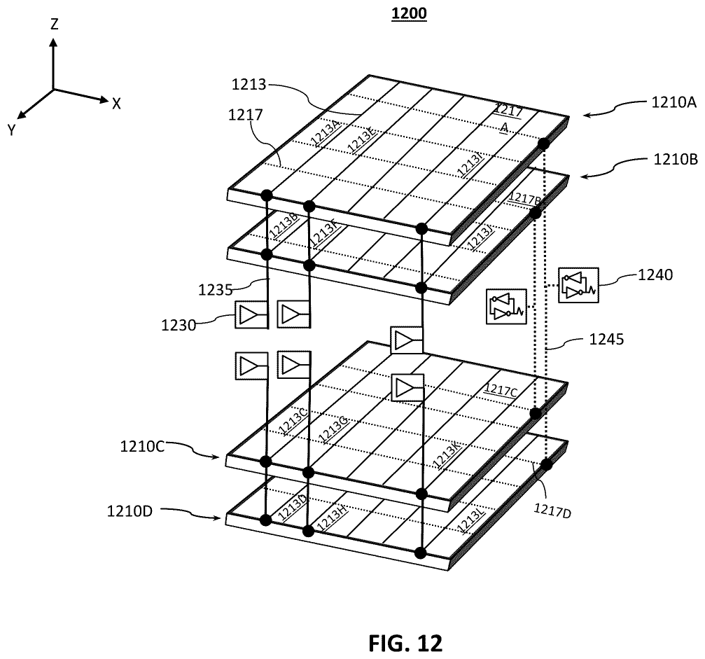

FIG. 12 illustrates an IC device 1200 with memory layers 1210A-1210D sharing word line drivers 1230 and sense amplifiers 1240 in a CMOS layer, according to some embodiments of the present disclosure. In the embodiments of FIG. 12, the CMOS layer is between the memory layers 1210B and 1210C, so that the memory layers 1210A and 1210B are at the frontside of the CMOS layer versus the memory layers 1210C and 1210D are at the backside of the CMOS layer. The four memory layers 1210A-1210D may be referred to as “memory layers 1210” or “memory layer 1210.” In other embodiments, the IC device 1200 may include a different number of memory layers at either side of the CMOS layer. For the purpose of illustration, the CMOS layer is not shown in FIG. 12. Also, the IC device 1200 may include other components that are not shown in FIG. 12, such as bonding layers, vias, and so on. The IC device 1200 may also be referred to as an IC assembly.

The CMOS layer provides power and signals to the memory layers 1210. The CMOS layer may also receive signals (e.g., data stored in the memory layers 1210) from the memory layers 1210. The CMOS layer may be an example of the logic die 310 in FIG. 3. In the embodiments of FIG. 12, the CMOS layer includes word line drivers 1230 (individually referred to as “word line driver 1230”) and sense amplifiers 1240 (individually referred to as “sense amplifier 1240”). Even though not shown in FIG. 12, the CMOS layer may include other components, such as row decoders, column decoders, SRAM arrays, and so on. The word line drivers 1230 may be separate from each other. In some embodiments, the word line drivers 1230 are separated from each other by one or more electrical insulators. The sense amplifiers 1240 may also be separate from each other. In some embodiments, the sense amplifiers 1240 are separated from each other by one or more electrical insulators.

Each memory layer 1210 includes word lines 1213 (individually referred to as “word line 1213”) and bit lines 1217 (individually referred to as “word line 1213”). Each memory layer 1210 may also include memory cells coupled to the word lines 1213 and bit lines 1217. The memory layers 1210 may be examples of the memory dies 320 in FIG. 3. In some embodiments, the word lines 1213 are coupled to the word line drivers 1230 in the CMOS layer, and the bit lines 1217 are coupled to the sense amplifiers 1240 in the CMOS layer.

For the purpose of simplicity and illustration, FIG. 12 shows connections between representative word lines 1213A-1213L and the word line drivers 1230 and connections between representative bit lines 1217A-1217D and sense amplifiers 1240. The IC device 1200 may include other connections between word lines 1213 and word line drivers 1230 or other connections between bit lines 1217 and sense amplifiers 1240. As shown in FIG. 12, the word lines 1213A, 1213E, and 1213I and bit line 1217A are in the memory layer 1210A; the word lines 1213B, 1213F, and 1213J and bit line 1217B are in the memory layer 1210B; the word lines 1213C, 1213G, and 1213K and bit line 1217C are in the memory layer 1210C; and the word lines 1213D, 1213H, and 1213L and bit line 1217D are in the memory layer 1210D.

The word lines 1213A-1213L are in six word line groups: a first word line group including the word lines 1213A and 1213B, a second word line group including the word lines 1213C and 1213D, a third word line group including the word lines 1213E and 1213F, a fourth word line group including the word lines 1213G and 1213H, a fifth word line group including the word lines 1213I and 1213J, and a sixth word line group including the word lines 1213K and 1213L. Each word line group includes two word lines 1213 that are in two memory layers 1210, respectively, which are at the same side of the CMOS layer. The six word line group are coupled to the six word line drivers 1230, respectively. The word line groups that includes word lines 1213 in the memory layers 1210A and 1210B at the frontside of the CMOS layers are referred to as “frontside word line groups,” and the word line drivers 1230 coupled to these word lines groups are referred to as “frontside word line driver.” The word line groups that include word lines 1213 in the memory layers 1210C and 1210D at the backside of the CMOS layers are referred to as “backside word line groups,” and the word line drivers 1230 coupled to these word lines groups are referred to as “backside word line driver.” Each word line group is coupled to a different word line driver 1230 through a conductive structure 1235. The conductive structure 1235 is connected to the two word lines 1213 in the word line group and to the corresponding word line driver 1230. The word lines 1213 in the same word line group may be activated by the same signal form the word line driver 1230.

The bit lines 1217A and 1217D, which are in memory layers 1210A and 1210D that are father from the CMOS layer, are coupled to one of the sense amplifiers 1240 through structures 1245 (individually referred to as “conductive structure 1245”). The sense amplifier 1240 coupled to the bit lines 1217A and 1217D is referred to as a “far sense amplifier.” The bit lines 1217B and 1217C, which are in memory layers 1217B and 1217C that are closer to the CMOS layer, are coupled to the other one of the sense amplifiers 1240 through additional structures 1245. The sense amplifier 1240 coupled to the bit lines 1217B and 1217D is referred to as a “near sense amplifier.” Each conductive structure 1245 is connected to one of the bitlines 1217A-1217D and the corresponding sense amplifier 1240. A conductive structure 1235 or 1245 may extend in a direction perpendicular to the memory layers 1210. Each conductive structure 1235 or 1245 may include one or more vias, including TSVs.

With the “near-far” word line drivers and “front-back” sense amplifiers arrangement, memory cells in the memory layers 1210 can still be separately accessed and activated, despite that the memory layers 1210 share the word line drivers 1230 and sense amplifiers 1240. Memory cells in different memory layers 1210 may have different memory addresses, based on which the memory cells may be located, selected, or accessed.

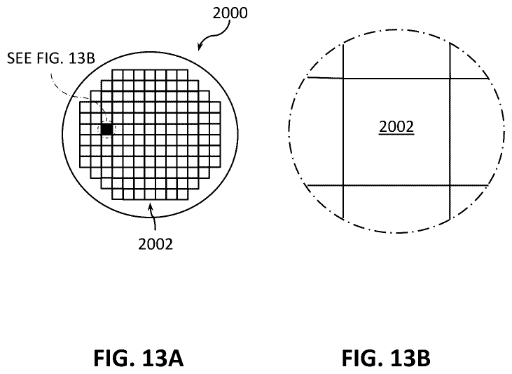

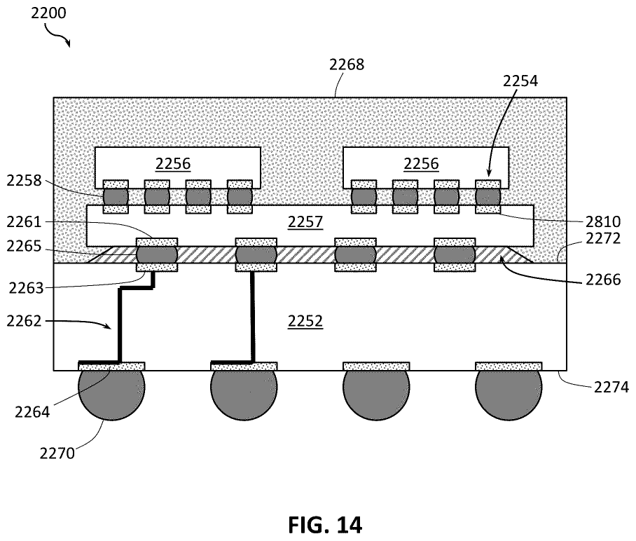

FIGS. 13A and 13B are top views of a wafer 2000 and dies 2002 that can facilitate stacked memory layers with one or more global bit lines or one or more global word lines, according to some embodiments of the disclosure. In some embodiments, the dies 2002 may be included in an IC package, according to some embodiments of the disclosure. For example, any of the dies 2002 may serve as any of the dies 2256 in an IC package 2200 shown in FIG. 14. Examples of the dies 2002 may include the logic die 310, the memory die 320A or 320B, the memory die 720, the logic die 730, and so on. The wafer 2000 may be composed of semiconductor material and may include one or more dies 2002 having IC devices formed on a surface of the wafer 2000. Examples of the wafer 2000 may include the wafer 712, the wafer 714, and so on.

Each of the dies 2002 may be a repeating unit of a semiconductor product that includes any suitable IC. After the fabrication of the semiconductor product is complete, the wafer 2000 may undergo a singulation process in which each of the dies 2002 is separated from one another to provide discrete “chips” of the semiconductor product. In particular, memory devices as disclosed herein may take or include components that take the form of the wafer 2000 (e.g., not singulated) or the form of the die 2002 (e.g., singulated). The die 2002 may include one or more diodes, one or more transistors (e.g., one or more III-N transistors as described herein) as well as, optionally, supporting circuitry to route electrical signals to the III-N diodes with n-doped wells and capping layers and III-N transistors, as well as any other IC components. In some embodiments, the wafer 2000 or the die 2002 may implement an electrostatic discharge (ESD) protection device, a radio frequency front-end device, a memory device (e.g., a SRAM device), a logic device (e.g., an AND, OR, NAND, or NOR gate), or any other suitable circuit element. Multiple ones of these devices may be combined on a single die 2002.

FIG. 14 is a side, cross-sectional view of an example IC package 2200 that may include stacked memory layers with one or more global bit lines or one or more global word lines, according to some embodiments of the disclosure. In some embodiments, the IC package 2200 may be a system-in-package (SiP). An example of the IC package 2200 may include the IC device 100, 200, 300, 400, or 500.

As shown in FIG. 14, the IC package 2200 may include a package substrate 2252. The package substrate 2252 may be formed of a dielectric material (e.g., a ceramic, a glass, a combination of organic and inorganic materials, a buildup film, an epoxy film having filler particles therein, etc., and may have embedded portions having different materials), and may have conductive pathways extending through the dielectric material between the face 2272 and the face 2274, or between different locations on the face 2272, and/or between different locations on the face 2274.

The package substrate 2252 may include conductive contacts 2263 that are coupled to conductive pathways 2262 through the package substrate 2252, allowing circuitry within the dies 2256 and/or the interposer 2257 to electrically couple to various ones of the conductive contacts 2264 (or to other devices included in the package substrate 2252, not shown).

The IC package 2200 may include an interposer 2257 coupled to the package substrate 2252 via conductive contacts 2261 of the interposer 2257, first-level interconnects 2265, and the conductive contacts 2263 of the package substrate 2252. The first-level interconnects 2265 illustrated in FIG. 14 are solder bumps, but any suitable first-level interconnects 2265 may be used. In some embodiments, no interposer 2257 may be included in the IC package 2200; instead, the dies 2256 may be coupled directly to the conductive contacts 2263 at the face 2272 by first-level interconnects 2265.

The IC package 2200 may include one or more dies 2256 coupled to the interposer 2257 via conductive contacts 2254 of the dies 2256, first-level interconnects 2258, and conductive contacts 2260 of the interposer 2257. The conductive contacts 2260 may be coupled to conductive pathways (not shown) through the interposer 2257, allowing circuitry within the dies 2256 to electrically couple to various ones of the conductive contacts 2261 (or to other devices included in the interposer 2257, not shown). The first-level interconnects 2258 illustrated in FIG. 14 are solder bumps, but any suitable first-level interconnects 2258 may be used. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

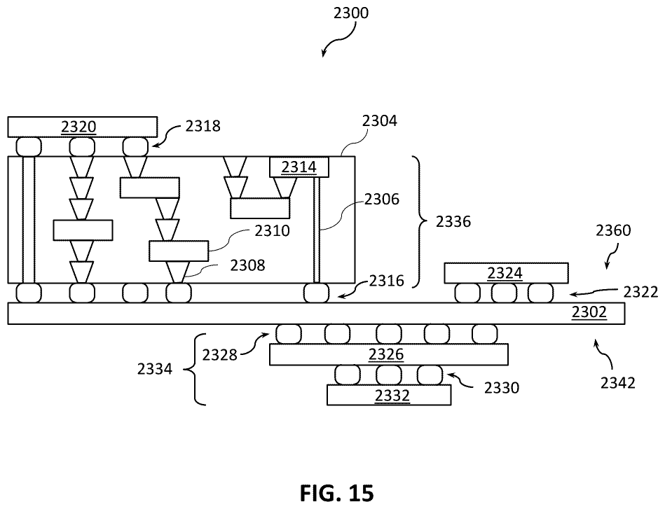

In some embodiments, an underfill material 2266 may be disposed between the package substrate 2252 and the interposer 2257 around the first-level interconnects 2265, and a mold compound 2268 may be disposed around the dies 2256 and the interposer 2257 and in contact with the package substrate 2252. In some embodiments, the underfill material 2266 may be the same as the mold compound 2268. Example materials that may be used for the underfill material 2266 and the mold compound 2268 are epoxy mold materials, as suitable. Second-level interconnects 2270 may be coupled to the conductive contacts 2264. The second-level interconnects 2270 illustrated in FIG. 14 are solder balls (e.g., for a ball grid array arrangement), but any suitable second-level interconnects 22770 may be used (e.g., pins in a pin grid array arrangement or lands in a land grid array arrangement). The second-level interconnects 2270 may be used to couple the IC package 2200 to another component, such as a circuit board (e.g., a motherboard), an interposer, or another IC package, as known in the art and as discussed below with reference to FIG. 15.

The dies 2256 may take the form of any of the embodiments of the die 2002 discussed herein and may include any of the embodiments of an IC device with stacked memory layers with one or more global bit lines or one or more global word lines. In embodiments in which the IC package 2200 includes multiple dies 2256, the IC package 2200 may be referred to as a multi-chip package. Importantly, even in such embodiments of an MCP implementation of the IC package 2200, one or more IC devices with stacked memory layers with one or more global bit lines or one or more global word lines may be provided in a single chip, in accordance with any of the embodiments described herein. The dies 2256 may include circuitry to perform any desired functionality. For example, one or more of the dies 2256 may be ESD protection dies, one or more of the dies 2256 may be logic dies (e.g., silicon-based dies), one or more of the dies 2256 may be memory dies (e.g., high bandwidth memory), etc. In some embodiments, the dies 2256 may include stacked memory layers with one or more global bit lines or one or more global word lines. In some embodiments, at least some of the dies 2256 may not include any III-N diodes with n-doped wells and capping layers.

The IC package 2200 illustrated in FIG. 14 may be a flip chip package, although other package architectures may be used. For example, the IC package 2200 may be a ball grid array (BGA) package, such as an embedded wafer-level ball grid array (eWLB) package. In another example, the IC package 2200 may be a wafer-level chip scale package (WLCSP) or a panel fan-out (FO) package. Although two dies 2256 are illustrated in the IC package 2200 of FIG. 14, an IC package 2200 may include any desired number of the dies 2256. An IC package 2200 may include additional passive components, such as surface-mount resistors, capacitors, and inductors disposed on the first face 2272 or the second face 2274 of the package substrate 2252, or on either face of the interposer 2257. More generally, an IC package 2200 may include any other active or passive components known in the art.

FIG. 15 is a cross-sectional side view of an IC device assembly 2300 that may include components having stacked memory layers with one or more global bit lines or one or more global word lines, according to some embodiments of the disclosure. The IC device assembly 2300 includes a number of components disposed on a circuit board 2302 (which may be, e.g., a motherboard). The IC device assembly 2300 includes components disposed on a first face 2340 of the circuit board 2302 and an opposing second face 2342 of the circuit board 2302; generally, components may be disposed on one or both faces 2340 and 2342. Any of the IC packages discussed below with reference to the IC device assembly 2300 may take the form of any of the embodiments of the IC package 2200 discussed above with reference to FIG. 14 (e.g., may include stacked memory layers with one or more global bit lines or one or more global word lines).

In some embodiments, the circuit board 2302 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2302. In other embodiments, the circuit board 2302 may be a non-PCB substrate.

The IC device assembly 2300 illustrated in FIG. 15 includes a package-on-interposer structure 2336 coupled to the first face 2340 of the circuit board 2302 by coupling components 2316. The coupling components 2316 may electrically and mechanically couple the package-on-interposer structure 2336 to the circuit board 2302, and may include solder balls (e.g., as shown in FIG. 14), male and female portions of a socket, an adhesive, an underfill material, and/or any other suitable electrical and/or mechanical coupling structure.

The package-on-interposer structure 2336 may include an IC package 2320 coupled to an interposer 2304 by coupling components 2318. The coupling components 2318 may take any suitable form for the application, such as the forms discussed above with reference to the coupling components 2316. The IC package 2320 may be or include, for example, a die (the die 2002 of FIG. 13B), an IC device (e.g., the IC device the IC device 100, 200, 300, 400, 500, 700, 1000, 1100, or 1200), or any other suitable component. Although a single IC package 2320 is shown in FIG. 15, multiple IC packages may be coupled to the interposer 2304; indeed, additional interposers may be coupled to the interposer 2304. The interposer 2304 may provide an intervening substrate used to bridge the circuit board 2302 and the IC package 2320. Generally, the interposer 2304 may spread a connection to a loose pitch or reroute a connection to a different connection. For example, the interposer 2304 may couple the IC package 2320 (e.g., a die) to a BGA of the coupling components 2316 for coupling to the circuit board 2302. In the embodiment illustrated in FIG. 15, the IC package 2320 and the circuit board 2302 are attached to opposing sides of the interposer 2304; in other embodiments, the IC package 2320 and the circuit board 2302 may be attached to a same side of the interposer 2304. In some embodiments, three or more components may be interconnected by way of the interposer 2304.

The interposer 2304 may be formed of an epoxy resin, a fiberglass-reinforced epoxy resin, a ceramic material, or a polymer material such as polyimide. In some implementations, the interposer 2304 may be formed of alternate rigid or flexible materials that may include the same materials described above for use in a semiconductor substrate, such as silicon, germanium, and other Group III-V and Group IV materials. The interposer 2304 may include metal interconnects 2308 and vias 2310, including but not limited to TSVs 2306. The interposer 2304 may further include embedded devices 2314, including both passive and active devices. Such devices may include, but are not limited to, capacitors, decoupling capacitors, resistors, inductors, fuses, diodes, transformers, sensors, ESD protection devices, and memory devices. More complex devices such as further RF devices, power amplifiers, power management devices, antennas, arrays, sensors, and microelectromechanical systems (MEMS) devices may also be formed on the interposer 2304. The package-on-interposer structure 2336 may take the form of any of the package-on-interposer structures known in the art. The interposer 2304 may be an embodiment of the interposers 319 or interposers 324 in FIG. 3.

The IC device assembly 2300 may include an IC package 2324 coupled to the first face 2340 of the circuit board 2302 by coupling components 2322. The coupling components 2322 may take the form of any of the embodiments discussed above with reference to the coupling components 2316, and the IC package 2324 may take the form of any of the embodiments discussed above with reference to the IC package 2320.

The IC device assembly 2300 illustrated in FIG. 15 includes a package-on-package structure 2334 coupled to the second face 2342 of the circuit board 2302 by coupling components 2328. The package-on-package structure 2334 may include an IC package 2326 and an IC package 2332 coupled together by coupling components such that the IC package 2326 is disposed between the circuit board 2302 and the IC package 2332. The coupling components 2328 and 2330 may take the form of any of the embodiments of the coupling components 2316 discussed above, and the IC packages 2326 and 2332 may take the form of any of the embodiments of the IC package 2320 discussed above. The package-on-package structure 2334 may be configured in accordance with any of the package-on-package structures known in the art.

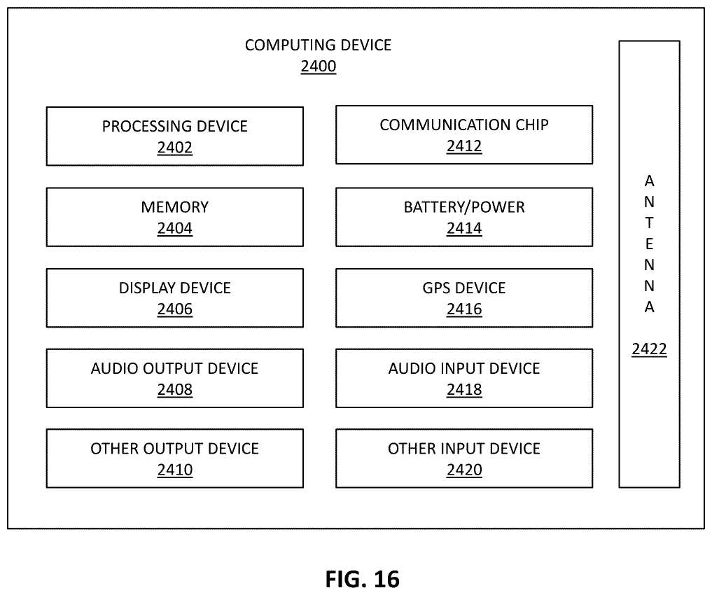

FIG. 16 is a block diagram of an example computing device 2400 that may include one or more components with stacked memory layers with one or more global bit lines or one or more global word lines, according to some embodiments of the disclosure. For example, any suitable ones of the components of the computing device 2400 may include a die (e.g., the die 2002 of FIG. 13B), according to some embodiments of the disclosure. Any of the components of the computing device 2400 may include an IC device (e.g., the IC device 100, 200, 300, 400, 500, 700, 1000, 1100, or 1200) and/or an IC package (e.g., the IC package 2200 of FIG. 14). Any of the components of the computing device 2400 may include an IC device assembly (e.g., the IC device assembly 2300 of FIG. 15).

A number of components are illustrated in FIG. 16 as included in the computing device 2400, but any one or more of these components may be omitted or duplicated, as suitable for the application. In some embodiments, some or all of the components included in the computing device 2400 may be attached to one or more motherboards. In some embodiments, some or all of these components are fabricated onto a single SoC (system-on-chip) die.

Additionally, in various embodiments, the computing device 2400 may not include one or more of the components illustrated in FIG. 16, but the computing device 2400 may include interface circuitry for coupling to the one or more components. For example, the computing device 2400 may not include a display device 2406, but may include display device interface circuitry (e.g., a connector and driver circuitry) to which a display device 2406 may be coupled. In another set of examples, the computing device 2400 may not include an audio input device 2418 or an audio output device 2408, but may include audio input or output device interface circuitry (e.g., connectors and supporting circuitry) to which an audio input device 2418 or audio output device 2408 may be coupled.

The computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2402 may include one or more digital signal processors (DSPs), application-specific ICs (ASICs), CPUs, GPUs, cryptoprocessors (specialized processors that execute cryptographic algorithms within hardware), server processors, or any other suitable processing devices. The computing device 2400 may include a memory 2404, which may itself include one or more memory devices such as SRAM, DRAM, nonvolatile memory (e.g., read-only memory (ROM)), flash memory, solid-state memory, and/or a hard drive. In some embodiments, the memory 2404 may include memory that shares a die with the processing device 2402. This memory may be used as cache memory and may include, e.g., SRAM.

In some embodiments, the computing device 2400 may include a communication chip 2412 (e.g., one or more communication chips). For example, the communication chip 2412 may be configured for managing wireless communications for the transfer of data to and from the computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2412 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2412 may operate in accordance with other wireless protocols in other embodiments. The computing device 2400 may include an antenna 2422 to facilitate wireless communications and/or to receive other wireless communications (such as AM or FM radio transmissions).

In some embodiments, the communication chip 2412 may manage wired communications, such as electrical, optical, or any other suitable communication protocols (e.g., the Ethernet). As noted above, the communication chip 2412 may include multiple communication chips. For instance, a first communication chip 2412 may be dedicated to shorter-range wireless communications such as Wi-Fi or Bluetooth, and a second communication chip 2412 may be dedicated to longer-range wireless communications such as global positioning system (GPS), EDGE, GPRS, CDMA, WiMAX, LTE, EV-DO, or others. In some embodiments, a first communication chip 2412 may be dedicated to wireless communications, and a second communication chip 2412 may be dedicated to wired communications.

In various embodiments, IC devices as described herein may be particularly advantageous for use as part of ESD circuits protecting power amplifiers, low-noise amplifiers, filters (including arrays of filters and filter banks), switches, or other active components. In some embodiments, IC devices as described herein may be used in PMICs, e.g., as a rectifying diode for large currents. In some embodiments, IC devices as described herein may be used in audio devices and/or in various input/output devices.

The computing device 2400 may include battery/power circuitry 2414. The battery/power circuitry 2414 may include one or more energy storage devices (e.g., batteries or capacitors) and/or circuitry for coupling components of the computing device 2400 to an energy source separate from the computing device 2400 (e.g., AC line power).

The computing device 2400 may include a display device 2406 (or corresponding interface circuitry, as discussed above). The display device 2406 may include any visual indicators, such as a heads-up display, a computer monitor, a projector, a touchscreen display, a liquid crystal display (LCD), a light-emitting diode display, or a flat panel display, for example.

The computing device 2400 may include an audio output device 2408 (or corresponding interface circuitry, as discussed above). The audio output device 2408 may include any device that generates an audible indicator, such as speakers, headsets, or earbuds, for example.

The computing device 2400 may include an audio input device 2418 (or corresponding interface circuitry, as discussed above). The audio input device 2418 may include any device that generates a signal representative of a sound, such as microphones, microphone arrays, or digital instruments (e.g., instruments having a musical instrument digital interface (MIDI) output).

The computing device 2400 may include a GPS device 2416 (or corresponding interface circuitry, as discussed above). The GPS device 2416 may be in communication with a satellite-based system and may receive a location of the computing device 2400, as known in the art.

The computing device 2400 may include another output device 2410 (or corresponding interface circuitry, as discussed above). Examples of the other output device 2410 may include an audio codec, a video codec, a printer, a wired or wireless transmitter for providing information to other devices, or an additional storage device.

The computing device 2400 may include another input device 2420 (or corresponding interface circuitry, as discussed above). Examples of the other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2400 may be any other electronic device that processes data.

The following paragraphs provide various examples of the embodiments disclosed herein.

Example 1 provides an integrated circuit (IC) device, including a first memory device, including a plurality of first memory cells arranged in columns, and a first bit line coupled to a column of first memory cells; a second memory device over the first memory device, the second memory device including a plurality of second memory cells arranged in rows, and a second bit line coupled to a column of second memory cells; one or more conductive structures between the first bit line and the second bit line, in which the first bit line is coupled to the second bit line through the one or more conductive structures; and a logic device over the first memory device and the second memory device, the logic device coupled to the first bit line or the second bit line.

Example 2 provides the IC device according to example 1, in which: the first memory device or the second memory device includes a first semiconductor structure having a first cross section, the logic device includes a second semiconductor structure having a second cross section, and the first cross section is smaller than the second cross section.

Example 3 provides the IC device according to example 1 or 2, in which: the first memory device includes a first sense amplifier coupled to the plurality of first memory cells, a first decoder coupled to the column of first memory cells, and a first buffer coupled to the plurality of first memory cells, and the second memory device includes second sense amplifier coupled to the plurality of second memory cells, a second decoder coupled to the column of second memory cells, and a second buffer coupled to the plurality of second memory cells.

Example 4 provides the IC device according to any one of examples 1-3, further including a third memory array over the first memory device and the second memory device, the third memory array including a plurality of third memory cells arranged in rows, and a third bit line coupled to a column of third memory cells, in which the third bit line is coupled to the first bit line and the second bit line by one or more additional conductive structures.

Example 5 provides the IC device according to example 4, in which the one or more conductive structures and the one or more additional conductive structures have a zigzag pattern in a plane that is perpendicular to a plane of the first memory device, the second memory device, or the third memory array.

Example 6 provides the IC device according to any one of examples 1-5, further including a power via coupled to the plurality of first memory cells; in which at least part of the power via is between the first memory device and the logic device, the logic device includes a power interconnect, and the power interconnect is coupled to the power via.

Example 7 provides the IC device according to any one of examples 1-6, in which: the plurality of first memory cells is arranged in rows, the first memory device further includes a first word line couple to a row of first memory cells, the plurality of second memory cells is arranged in rows, the second memory device further includes a second word line couple to a row of second memory cells, and the first word line is separated from the second word line by an electrical insulator.

Example 8 provides an integrated circuit (IC) device, including a first memory device, including a plurality of first memory cells arranged in rows, and a first word line coupled to a row of first memory cells; a second memory device over the first memory device, the second memory device including a plurality of second memory cells arranged in rows, and a second word line coupled to a row of second memory cells; one or more conductive structures between the first word line and the second word line, in which the first word line is coupled to the second word line through the one or more conductive structures; and a logic device over the first memory device and the second memory device, the logic device coupled to the first word line or the second word line.

Example 9 provides the IC device according to example 8, in which: the first memory device or the second memory device includes a first semiconductor structure having a first cross section, the logic device includes a second semiconductor structure having a second cross section, and the first cross section is smaller than the second cross section.

Example 10 provides the IC device according to example 8 or 9, in which: the first memory device includes a first sense amplifier coupled to the plurality of first memory cells, a first decoder coupled to the row of first memory cells, and a first buffer coupled to the plurality of first memory cells, and the second memory device includes second sense amplifier coupled to the plurality of second memory cells, a second decoder coupled to the row of second memory cells, and a second buffer coupled to the plurality of second memory cells.

Example 11 provides the IC device according to any one of examples 8-10, further including a third memory array over the first memory device and the second memory device, the third memory array including a plurality of third memory cells arranged in rows, and a third word line coupled to a column of third memory cells, in which the third word line is coupled to the first word line and the second word line by one or more additional conductive structures.

Example 12 provides the IC device according to example 11, in which the one or more conductive structures and the one or more additional conductive structures have a zigzag pattern in a plane that is perpendicular to a plane of the first memory device, the second memory device, or the third memory array.

Example 13 provides the IC device according to any one of examples 8-12, further including a power via coupled to the plurality of first memory cells; in which at least part of the power via is between the first memory device and the logic device, the logic device includes a power interconnect, and the power interconnect is coupled to the power via.

Example 14 provides the IC device according to any one of examples 8-13, in which: the plurality of first memory cells is arranged in columns, the first memory device further includes a first bit line couple to a column of first memory cells, the plurality of second memory cells is arranged in columns, the second memory device further includes a second bit line couple to a column of second memory cells, and the first bit line is separated from the second bit line by an electrical insulator.

Example 15 provides an integrated circuit (IC) device, including a first memory die including first memory transistors, an individual first memory transistor including a first electrode over a first semiconductor region; a second memory die over the first memory die, the second memory die including second memory transistors, an individual second memory transistor including a second electrode over a second semiconductor region; one or more conductive structures between the first electrode and the second electrode, in which the first electrode is coupled to the second electrode through the one or more conductive structures; and a logic die over the first memory die and the second memory die, the logic die including a logic circuit coupled to the first electrode or the second electrode.

Example 16 provides the IC device according to example 15, in which the first semiconductor region is a channel region of the first memory transistor, and the second semiconductor region is a channel region of the second memory transistor.

Example 17 provides the IC device according to example 15 or 16, in which the first semiconductor region is a source or drain region of the first memory transistor, and the second semiconductor region is a source or drain region of the second memory transistor.

Example 18 provides the IC device according to any one of examples 15-17, in which: the first memory transistor further includes a third electrode over a third semiconductor region, the second memory transistor further includes a fourth electrode over a fourth semiconductor region, and the third electrode is separated from the fourth electrode by an electrical insulator.

Example 19 provides the IC device according to any one of examples 15-18, in which: the first semiconductor region is in a first semiconductor structure having a first cross section, the second semiconductor region is in a second semiconductor structure having a second cross section, and the first cross section is smaller than the second cross section.

Example 20 provides the IC device according to any one of examples 15-19, further including a power via coupled to the first memory transistor and the second memory transistor; in which at least part of the power via is between the first memory die or the second memory die and the logic die, the logic circuit further includes a power interconnect, and the power interconnect is coupled to the power via.

Example 21 provides an IC package, including the IC device any one of examples 1-20; and a further IC component, coupled to the IC device.

Example 22 provides the IC package according to example 21, where the further IC component includes one of a package substrate, an interposer, or a further IC die.

Example 23 provides the IC package according to example 21 or 22, where the IC device may include, or be a part of, at least one of a memory device, a computing device, a wearable device, a handheld electronic device, and a wireless communications device.

Example 24 provides an electronic device, including a carrier substrate; and the IC package according to any one of examples 21-23, coupled to the carrier substrate.

Example 25 provides the electronic device according to example 24, where the carrier substrate is a motherboard.

Example 26 provides the electronic device according to example 24, where the carrier substrate is a PCB.

Example 27 provides the electronic device according to any one of examples 24-26, where the electronic device is a wearable electronic device or handheld electronic device.

Example 28 provides the electronic device according to any one of examples 24-27, where the electronic device further includes one or more communication chips and an antenna.

Example 29 provides the electronic device according to any one of examples 24-28, where the electronic device is an RF transceiver.

Example 30 provides the electronic device according to any one of examples 24-28, where the electronic device is one of a switch, a power amplifier, a low-noise amplifier, a filter, a filter bank, a duplexer, an upconverter, or a downconverter of an RF communications device, e.g., of an RF transceiver.

Example 31 provides the electronic device according to any one of examples 24-30, where the electronic device is a computing device.

Example 32 provides the electronic device according to any one of examples 24-31, where the electronic device is included in a base station of a wireless communication system.

Example 33 provides the electronic device according to any one of examples 24-31, where the electronic device is included in a user equipment device of a wireless communication system.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) device, comprising:
a first memory device, comprising:
a plurality of first memory cells arranged in columns, and
a first bit line coupled to a column of first memory cells;
a second memory device over the first memory device, the second memory device comprising:
a plurality of second memory cells arranged in columns, and
a second bit line coupled to a column of second memory cells;
one or more conductive structures between the first bit line and the second bit line, wherein the first bit line is coupled to the second bit line through the one or more conductive structures; and
a logic device over the first memory device and the second memory device, the logic device coupled to the first bit line or the second bit line.

2. The IC device according to claim 1, wherein:
the first memory device or the second memory device comprises a first semiconductor structure having a first cross section,
the logic device comprises a second semiconductor structure having a second cross section, and
the first cross section is smaller than the second cross section.

3. The IC device according to claim 1, wherein:
the first memory device comprises a first sense amplifier coupled to the plurality of first memory cells, a first decoder coupled to the column of first memory cells, and a first buffer coupled to the plurality of first memory cells, and
the second memory device comprises second sense amplifier coupled to the plurality of second memory cells, a second decoder coupled to the column of second memory cells, and a second buffer coupled to the plurality of second memory cells.

4. The IC device according to claim 1, further comprising:
a third memory array over the first memory device and the second memory device, the third memory array comprising:
a plurality of third memory cells arranged in columns, and
a third bit line coupled to a column of third memory cells,
wherein the third bit line is coupled to the first bit line and the second bit line by one or more additional conductive structures.

5. The IC device according to claim 4, wherein the one or more conductive structures and the one or more additional conductive structures have a zigzag pattern in a plane that is perpendicular to a plane of the first memory device, the second memory device, or the third memory array.

6. The IC device according to claim 1, further comprising:
a power via coupled to the plurality of first memory cells,
wherein at least part of the power via is between the first memory device and the logic device, the logic device comprises a power interconnect, and the power interconnect is coupled to the power via.

7. The IC device according to claim 1, wherein:
the plurality of first memory cells is arranged in rows,
the first memory device further comprises a first word line couple to a row of first memory cells,
the plurality of second memory cells is arranged in rows,
the second memory device further comprises a second word line couple to a row of second memory cells, and
the first word line is separated from the second word line by an electrical insulator.

8. An integrated circuit (IC) device, comprising:
a first memory device, comprising:
a plurality of first memory cells arranged in rows, and
a first word line coupled to a row of first memory cells;
a second memory device over the first memory device, the second memory device comprising:
a plurality of second memory cells arranged in rows, and
a second word line coupled to a row of second memory cells;
one or more conductive structures between the first word line and the second word line, wherein the first word line is coupled to the second word line through the one or more conductive structures; and
a logic device over the first memory device and the second memory device, the logic device coupled to the first word line or the second word line.

9. The IC device according to claim 8, wherein:
the first memory device or the second memory device comprises a first semiconductor structure having a first cross section,
the logic device comprises a second semiconductor structure having a second cross section, and
the first cross section is smaller than the second cross section.

10. The IC device according to claim 8, wherein:
the first memory device comprises a first sense amplifier coupled to the plurality of first memory cells, a first decoder coupled to the row of first memory cells, and a first buffer coupled to the plurality of first memory cells, and
the second memory device comprises second sense amplifier coupled to the plurality of second memory cells, a second decoder coupled to the row of second memory cells, and a second buffer coupled to the plurality of second memory cells.

11. The IC device according to claim 8, further comprising:
a third memory array over the first memory device and the second memory device, the third memory array comprising:
a plurality of third memory cells arranged in rows, and
a third word line coupled to a row of third memory cells,
wherein the third word line is coupled to the first word line and the second word line by one or more additional conductive structures.

12. The IC device according to claim 11, wherein the one or more conductive structures and the one or more additional conductive structures have a zigzag pattern in a plane that is perpendicular to a plane of the first memory device, the second memory device, or the third memory array.

13. The IC device according to claim 8, further comprising:
a power via coupled to the plurality of first memory cells,
wherein at least part of the power via is between the first memory device and the logic device, the logic device comprises a power interconnect, and the power interconnect is coupled to the power via.

14. The IC device according to claim 8, wherein:
the plurality of first memory cells is arranged in columns,
the first memory device further comprises a first bit line couple to a column of first memory cells,
the plurality of second memory cells is arranged in columns,
the second memory device further comprises a second bit line couple to a column of second memory cells, and
the first bit line is separated from the second bit line by an electrical insulator.

15. An integrated circuit (IC) device, comprising:
a first memory die comprising first memory transistors, an individual first memory transistor comprising a first electrode over a first semiconductor region;
a second memory die over the first memory die, the second memory die comprising second memory transistors, an individual second memory transistor comprising a second electrode over a second semiconductor region;
one or more conductive structures between the first electrode and the second electrode,
wherein the first electrode is coupled to the second electrode through the one or more conductive structures; and
a logic die over the first memory die and the second memory die, the logic die comprising a logic circuit coupled to the first electrode or the second electrode.

16. The IC device according to claim 15, wherein the first semiconductor region is a channel region of the first memory transistor, and the second semiconductor region is a channel region of the second memory transistor.

17. The IC device according to claim 15, wherein the first semiconductor region is a source or drain region of the first memory transistor, and the second semiconductor region is a source or drain region of the second memory transistor.

18. The IC device according to claim 15, wherein:
the first memory transistor further comprises a third electrode over a third semiconductor region,
the second memory transistor further comprises a fourth electrode over a fourth semiconductor region, and
the third electrode is separated from the fourth electrode by an electrical insulator.

19. The IC device according to claim 15, wherein:
the first semiconductor region is in a first semiconductor structure having a first cross section,
the second semiconductor region is in a second semiconductor structure having a second cross section, and
the first cross section is smaller than the second cross section.

20. The IC device according to claim 15, further comprising:
a power via coupled to the first memory transistor and the second memory transistor;
wherein at least part of the power via is between the first memory die or the second memory die and the logic die, the logic circuit further comprises a power interconnect, and the power interconnect is coupled to the power via.
